(19) United States
(12) Patent Application Publication
(10) Pub. No.: US 2026/0096270 A1
(43) Pub. Date: Apr. 2, 2026

(54) DISPLAY DEVICE AND ELECTRONIC DEVICE INCLUDING THE SAME

(71) Applicant: Samsung Display Co., Ltd., Yongin-si (KR)

(72) Inventors: Seongwon Kim, Yongin-si (KR); Kyungho Kim, Yongin-si (KR); Younjoo Lee, Yongin-si (KR)

(21) Appl. No.: 19/318,050

(22) Filed: Sep. 3, 2025

(30) Foreign Application Priority Data
Sep. 30, 2024 (KR) 10-2024-0133252

(51) Int. Cl. H10H 29/851; H10H 29/85; H10H 29/853; H10H 29/855; H10K 59/126; H10K 59/38; H10K 59/80; H10K 77/10; H10K 102/00

(52) U.S. Cl. CPC H10H 29/8512; H10H 29/8508; H10H 29/853; H10H 29/855; H10K 59/126; H10K 59/38; H10K 59/873; H10K 77/111; H10K 2102/311

(57) ABSTRACT

A display device includes a substrate including island portions spaced apart from each other, defining an opening between the island portions, and including a bridge portion connecting the island portions, a light-emitting element above the island portions, and a luminance compensation layer above the bridge portion, and further including a color conversion material configured to change color in response to stress.

### CROSS-REFERENCE TO RELATED APPLICATION

This application claims priority to and the benefit of Korean Patent Application No. 10-2024-0133252, filed on Sep. 30, 2024, in the Korean Intellectual Property Office, the disclosure of which is incorporated by reference herein in its entirety.

### BACKGROUND

### 1. Field

Aspects of embodiments of the present disclosure relate to a flexible display device.

### 2. Description of the Related Art

Due to the development of display devices configured to visually display electrical signals, various kinds of display devices having suitable characteristics, such as being thin and lightweight, and having low power consumption, have been introduced. For example, flexible display devices that may be folded or rolled have been introduced. Recently, there has been ongoing research and development on stretchable display devices capable of being changed into various shapes.

The above information disclosed in this Background section is only for enhancement of understanding of the background of the present disclosure and therefore it may contain information that does not form the prior art.

### SUMMARY

One or more embodiments include a flexible display device, for example, a stretchable display device.

However, these aspects are merely examples, and the scope of the disclosure is not limited thereto.

Additional aspects will be set forth in part in the description which follows and, in part, will be apparent from the description, or may be learned by practice of the presented embodiments of the disclosure.

According to one or more embodiments of the disclosure, there is provided a display device including a substrate including island portions spaced apart from each other, defining an opening between the island portions, and including a bridge portion connecting the island portions, a light-emitting element above the island portions, and a luminance compensation layer above the bridge portion, and further including a color conversion material configured to change color in response to stress.

The color conversion material may include a material represented by Formula 1

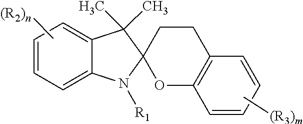

wherein, in Formula 1 R1 is a substituted or unsubstituted alkyl group having 1 carbon atom to 20 carbon atoms, R2 and R3 are independently a hydrogen atom, a deuterium atom, a halogen atom, a nitro group, a substituted or unsubstituted oxy group, a substituted or unsubstituted alkyl group having 1 carbon atom to 20 carbon atoms, a substituted or unsubstituted aryl group having 6 ring-forming carbon atoms to 30 ring-forming carbon atoms, or a substituted or unsubstituted heteroaryl group having 2 ring-forming carbon atoms to 30 ring-forming carbon atoms, and m and n are independently an integer from 0 to 4.

A luminance of the luminance compensation layer may be configured to increase in response to stress applied to the bridge portion increasing.

The luminance compensation layer may further include a base resin.

The luminance compensation layer may be spaced apart from the island portions.

The display device may further include at least one groove defined between the island portions and the bridge portion in plan view.

The luminance compensation layer may be separated from the at least one groove in plan view.

The display device may further a protective layer above the island portions to encapsulate the light-emitting element.

The protective layer may at least partially overlap the at least one groove, and may be spaced apart from the luminance compensation layer.

The display device may further an insulating layer above the bridge portion, and having a concavo-convex structure, wherein the luminance compensation layer is directly on the concavo-convex structure of the insulating layer.

The bridge portion may include a first bridge portion and a second bridge portion connected to one of the island portions, and extending in different directions, respectively, wherein the luminance compensation layer further includes a first luminance compensation layer above the first bridge portion, and a second luminance compensation layer above the second bridge portion.

The first luminance compensation layer may be configured to emit light of a first color, wherein the second luminance compensation layer is configured to emit light of a second color that is different from the first color.

The first luminance compensation layer and the second luminance compensation layer may be configured to emit light of a same color.

The luminance compensation layer may include sub-luminance compensation layers spaced apart from each other, wherein the sub-luminance compensation layers include a first sub-luminance compensation layer and a second sub-luminance compensation layer adjacent to each other, and configured to emit light of different respective colors.

The bridge portion may have a first width, wherein the luminance compensation layer has a second width that is substantially equal to the first width.

The bridge portion may have a first width, wherein the luminance compensation layer has a second width that is less than the first width.

The luminance compensation layer may be at an edge area of the bridge portion adjacent the island portions.

The display device may further a light-blocking layer around the luminance compensation layer in plan view.

According to one or more embodiments of the present disclosure, there is provided an electronic device including a display device including a substrate including island portions spaced apart from each other, defining an opening between the island portions, and further including a bridge portion connecting the island portions, a light-emitting element above the island portions, and a luminance compensation layer above the bridge portion, and including a color conversion material configured to change color in response to stress.

The electronic device may further include a wearable device, a medical device, a device for education, a robot, a device for a vehicle, a device for commercial films or exhibitions, or a controller.

### BRIEF DESCRIPTION OF THE DRAWINGS

The above and other aspects of some embodiments of the disclosure will be more apparent from the following description taken in conjunction with the accompanying drawings, in which:

FIG. 1 is a perspective view schematically illustrating a display device according to one or more embodiments of the present disclosure;

FIGS. 2A and 2B are perspective views each illustrating a state in which the display device illustrated in FIG. 1 is stretched in a first direction according to one or more embodiments of the present disclosure;

FIG. 2C is a perspective view illustrating a state in which the display device illustrated in FIG. 1 is stretched in a second direction according to one or more embodiments of the present disclosure;

FIG. 2D is a perspective view illustrating a state in which the display device illustrated in FIG. 1 is stretched in the first direction and the second direction according to one or more embodiments of the present disclosure;

FIG. 2E is a perspective view illustrating a state in which the display device illustrated in FIG. 1 is stretched in a third direction according to one or more embodiments of the present disclosure;

FIG. 3 is a plan view schematically illustrating a display device according to one or more embodiments of the present disclosure;

FIGS. 4A to 4C are each an enlarged plan view of a portion IV illustrated in FIG. 3 as a portion of a display device according to one or more embodiments of the present disclosure;

FIG. 5 is a cross-sectional view illustrating a first island portion and a first bridge portion arranged in a display area of a display device according to one or more embodiments of the present disclosure;

FIG. 6A to 6C are each an equivalent circuit diagram of a subpixel of a display device according to one or more embodiments of the present disclosure;

FIG. 7A and FIG. 7B are each a cross-sectional view schematically illustrating a light-emitting element of a display device according to one or more embodiments of the present disclosure;

FIGS. 8A to 8C are cross-sectional views each schematically illustrating a portion of a display device according to one or more embodiments of the present disclosure;

FIGS. 9A to 9C are plan views each schematically illustrating a portion of a display device according to one or more embodiments of the present disclosure;

FIGS. 10 and 11 are plan views schematically illustrating a portion of a display device according to one or more embodiments of the present disclosure;

FIGS. 12A and 12B are plan views schematically illustrating a portion of a display device according to one or more embodiments of the present disclosure;

FIGS. 13A to 13C are plan views each schematically illustrating a portion of a display device according to one or more embodiments of the present disclosure;

FIGS. 14A and 14B are plan views each schematically illustrating a portion of a display device according to one or more embodiments of the present disclosure;

FIG. 15 is a cross-sectional view of the display device taken along the line III-III illustrated in FIG. 14B according to one or more embodiments of the present disclosure;

FIGS. 16A and 16B are plan views schematically illustrating a portion of a display device according to one or more embodiments of the present disclosure;

FIG. 17 is a cross-sectional view of the display device taken along the line IV-IV illustrated in FIG. 16A according to one or more embodiments of the present disclosure; and

FIGS. 18A to 18G are perspective views schematically illustrating embodiments of an electronic device including a display device according to one or more embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

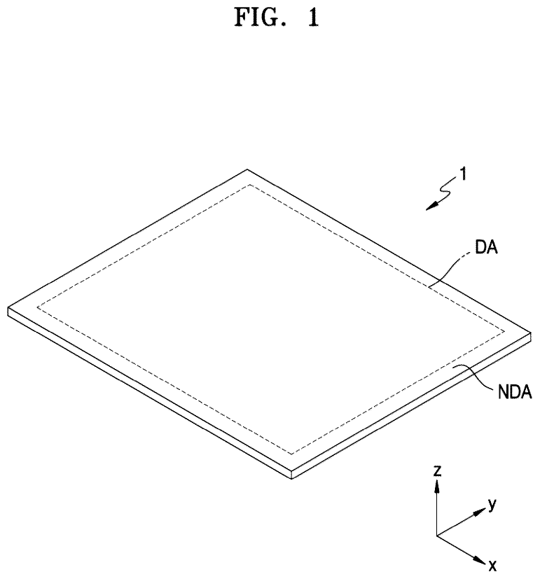

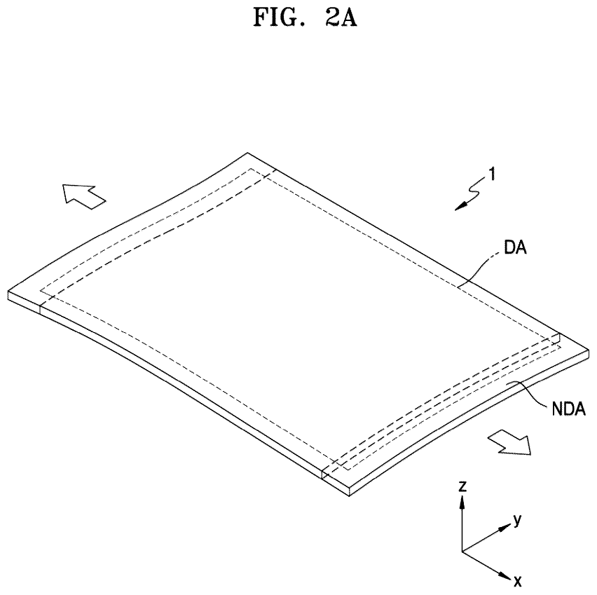

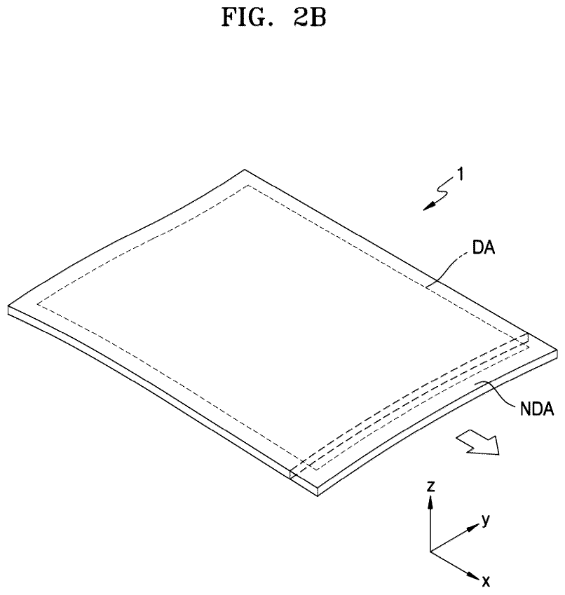

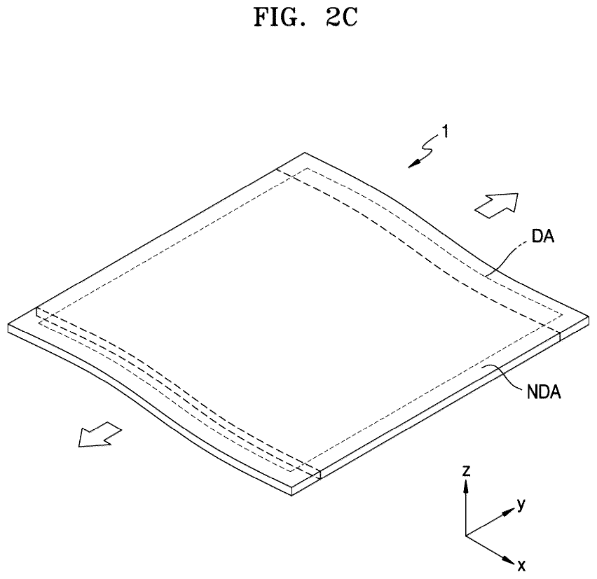

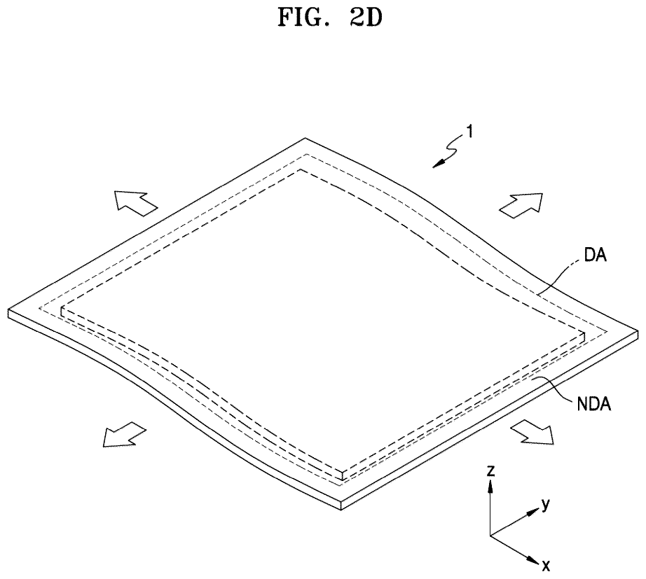

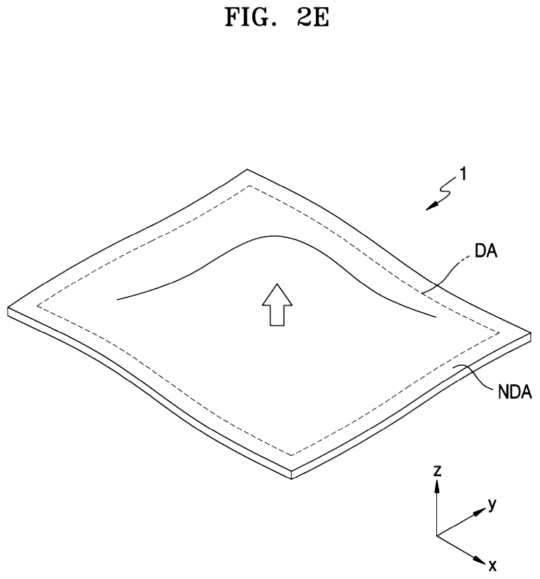

FIG. 1 is a perspective view schematically illustrating the display device 1 according to one or more embodiments of the present disclosure. FIGS. 2A and 2B are perspective views each illustrating a state in which the display device 1 illustrated in FIG. 1 is stretched in a first direction according to one or more embodiments of the present disclosure. FIG. 2C is a perspective view illustrating a state in which the display device 1 illustrated in FIG according to one or more embodiments of the present disclosure. 1 is stretched in a second direction. FIG. 2D is a perspective view illustrating a state in which the display device 1 illustrated in FIG. 1 is stretched in the first direction and the second direction according to one or more embodiments of the present disclosure. FIG. 2E is a perspective view illustrating a state in which the display device 1 illustrated in FIG. 1 is stretched in a third direction according to one or more embodiments of the present disclosure.

Referring to FIG. 1, the display device 1 may include a display area DA and a non-display area NDA. The display area DA may include a plurality of pixels. The display device 1 may be configured to provide corresponding images by using light emitted from the plurality of pixels. The non-display area NDA may be arranged outside the display area DA. The non-display area NDA, in which pixels are not arranged, may generally surround the display area DA.

The display device 1 may be stretched or contracted in various directions. The display device 1 may be stretched in the first direction (e.g., an x direction and/or a −x direction) due to an external force applied by an external object or a user. In one or more embodiments, as illustrated in FIGS. 2A and 2B, the display area DA and/or the non-display area NDA of the display device 1 may be stretched in the first direction (for example, the x direction and/or the −x direction). For example, the display device 1 may be stretched in the x direction and −x direction as illustrated in FIG. 2A, or may be stretched in the x direction with a side of the display device 1 fixed, as illustrated in FIG. 2B.

The display device 1 may be stretched in the second direction (for example, a y direction and/or a −y direction) due to an external force applied by an external object or a user. In one or more embodiments, as illustrated in FIG. 2C, the display area DA and/or the non-display area NDA of the display device 1 may be stretched in the y direction and the −y direction. In one or more other embodiments, the display device 1 may be stretched in the y direction or the −y direction with a side of the display device 1 fixed.

The display device 1 may be stretched in a plurality of directions, for example, the first direction (e.g., the x direction and/or the −x direction) and the second direction (e.g., the y direction and/or the −y direction), due to an external force applied by an external object or a portion of a human body. As illustrated in FIG. 2D, the display area DA and/the non-display area NDA of the display device 1 may be stretched in the +x directions and the +y directions.

The display device 1 may be stretched in the third direction (e.g., a z direction or the −z direction) due to an external force applied by an external object or a portion of a human body. FIG. 2E illustrates that in one or more embodiments a portion of the display device 1, (e.g., a portion of the display area DA), may protrude in the z direction. In one or more other embodiments, a portion of the display device 1, e.g., a portion of the display area DA, may protrude in the −z direction (e.g., may be recessed in the z direction).

Although FIGS. 2A to 2E illustrate that the display device 1 is stretched in the first direction, the second direction, and/or the third direction, the disclosure is not limited thereto. In one or more other embodiments, the display device 1 may be variously modified into amorphous shapes. For example, the display device 1 may be bent or twisted with two or more axes.

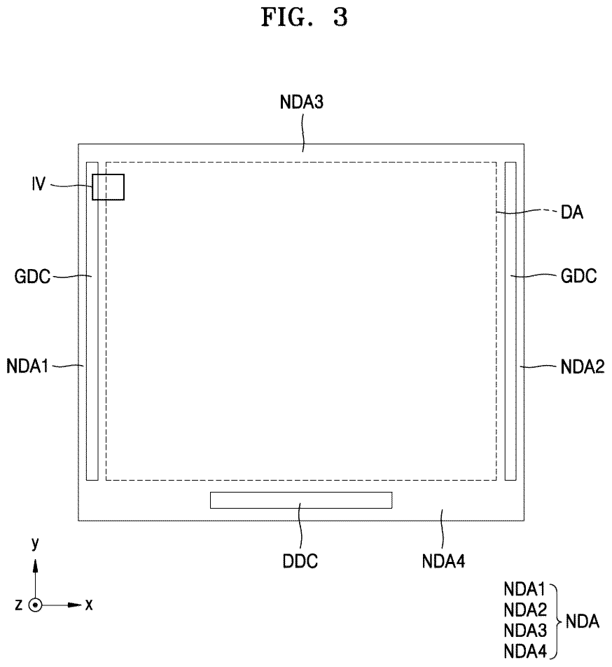

FIG. 3 is a plan view schematically illustrating the display device 1 according to one or more embodiments of the present disclosure.

The plurality of pixels may be arranged in the display area DA of the display device 1. Each of the plurality of pixels may include subpixels emitting light of various colors. Light-emitting elements corresponding to the subpixels may be arranged in the display area DA. The light-emitting elements may be arranged in the display area DA, and circuits configured to provide electrical signals to transistors electrically connected to the light-emitting elements may be in the non-display area NDA around the display area DA. A gate-driving circuit GDC may be arranged in each of a first non-display area NDA1 and a second non-display area NDA2 arranged at two sides with the display area DA therebetween. The gate-driving circuit GDC may include a plurality of drivers configured to provide electrical signals to gate electrodes of transistors electrically connected to the light-emitting elements. Although FIG. 3 illustrates that the gate-driving circuit GDC is arranged in each of the first non-display area NDA1 and the second non-display area NDA2, the disclosure is not limited thereto. In one or more other embodiments, the gate-driving circuit GDC may be arranged in any one of the first non-display area NDA1 or the second non-display area NDA2.

A data-driving circuit DDC may be arranged in a third non-display area NDA3 and/or a fourth non-display area NDA4 connecting the first non-display area NDA1 and the second non-display area NDA2. In one or more embodiments, FIG. 3 illustrates that the data-driving circuit DDC may be arranged in the fourth non-display area NDA4. In one or more other embodiments, the data-driving circuit DDC may be arranged in each of the third non-display area NDA3 and the fourth non-display area NDA4.

Although FIG. 3 illustrates that the data-driving circuit DDC is arranged in the fourth non-display area NDA4 of the display device 1, the disclosure is not limited thereto. In one or more other embodiments, the display device 1 may further include a flexible circuit board electrically connected through a terminal portion arranged in the fourth non-display area NDA4, and the data-driving circuit DDC may be arranged on the flexible circuit board.

In one or more other embodiments, an elongation (e.g., a rate of change of length, or ΔL/L) of the non-display area NDA may be equal to or less than an elongation of the display area DA. In one or more embodiments, elongation of the non-display area NDA may differ according to areas. For example, the first non-display area NDA1, the second non-display area NDA2, and the third non-display area NDA3 may have a substantially same elongation, but an elongation of the fourth non-display area NDA4 may be less than the elongation of each of the first non-display area NDA1, the second non-display area NDA2, and the third non-display area NDA3. An elongation may be a length of a direction of the display device 1 changes in response to an external force in the same direction.

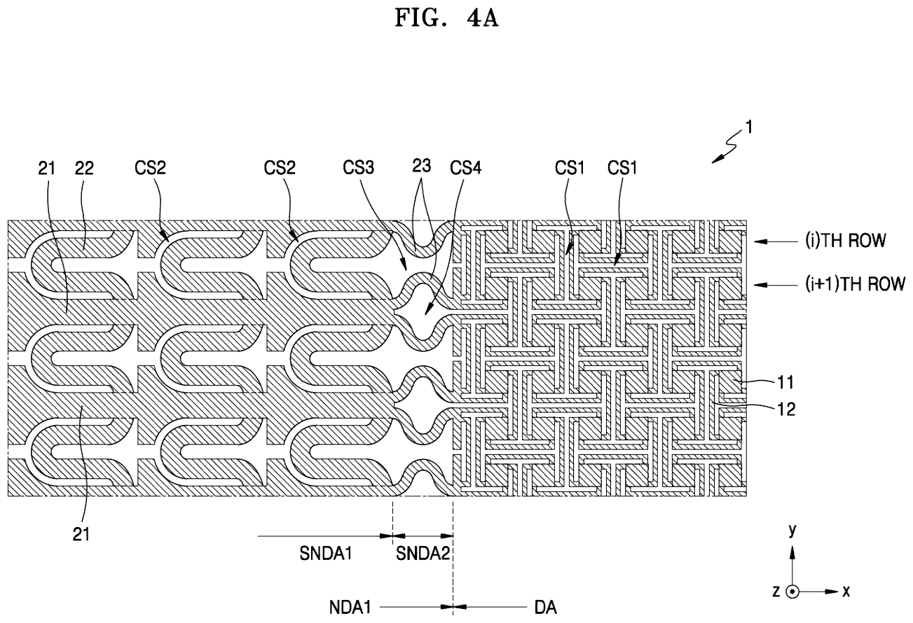

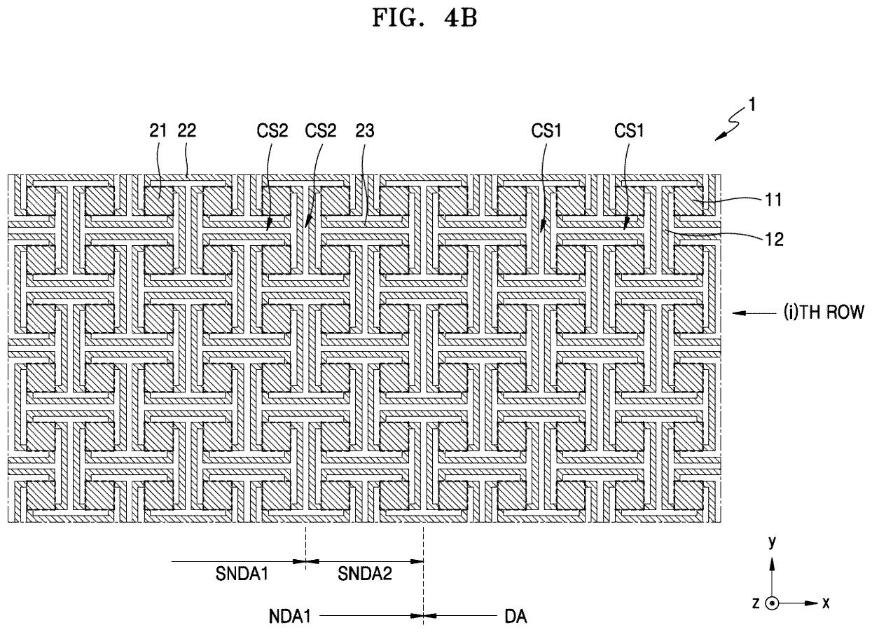

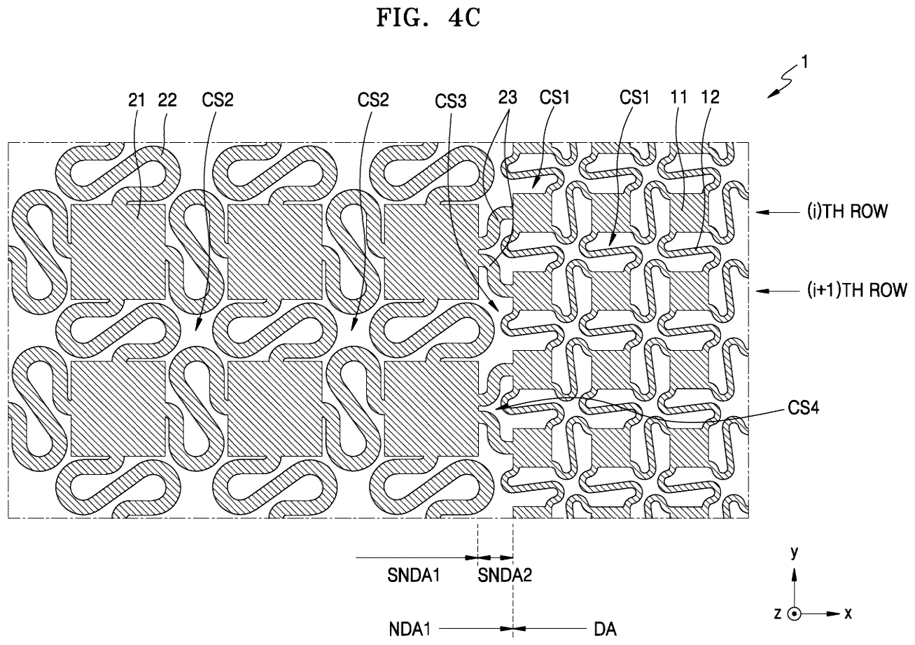

FIG. 4A is an enlarged plan view of a portion IV illustrated in FIG. 3 as a portion of the display device 1 according to one or more embodiments of the present disclosure.

Referring to FIG. 4A, the display area DA of the display device 1 may include a plurality of first island portions 11 spaced apart from one another in the first direction 1 (e.g., the x direction or the −y direction) and a plurality of first bridge portions 12 connecting the first island portions 11 adjacent to each other.

Each of the first island portions 11 may be connected to the plurality of first bridge portions 12. For example, each of the first island portions 11 may be connected to four of the first island portions 11. Two of the first bridge portions 12 may be arranged at two sides of the first island portion 11 in the first direction (e.g., the x direction or the −x direction), and the other two of the first bridge portions 12 may be arranged at the other two sides of the first island portion 11 in the second direction (e.g., the y direction or the −y direction). In one or more embodiments, four of the first bridge portions 12 may be respectively connected to four sides of the first island portion 11. Four of the first bridge portions 12 may be respectively adjacent to corners of the first island portion 11.

The first bridge portions 12 may be spaced apart from each other due to a first opening portion CS1 between the first bridge portions 12. In one or more embodiments, first opening portions CS1 having a shape approximately like the letter “H” and first opening portions CS1 having a shape approximately like the letter “I”, where the shape like the letter “I” is obtained by rotating the shape like the letter “H” by 90°, may be alternately and repeatedly arranged in the first direction (e.g., the x direction or the −x direction) and the second direction (e.g., the y direction or the −y direction). Two end portions of each of the first bridge portions 12 may be respectively connected to each of the first island portions 11 adjacent to each other, and a side of each of the first bridge portions 12 may be spaced apart from a side of the first island portions 11 adjacent to each other and/or a side of another first bridge portion 12 by the first opening portion CS1.

In the non-display area NDA (e.g., the first non-display area NDA illustrated FIG. 4A) the display device 1 may include second island portions 21 spaced apart from one another and second bridge portions 22 each connecting second island portions 21 adjacent to each other.

Each of the second island portions 21 may extend in the first direction (e.g., the x direction or the −x direction). The second island portions 21 may be spaced apart from one another in the second direction (e.g., the y direction or the −y direction) crossing the first direction (e.g., the x direction or the −x direction). Each of the second island portions 21 may include drivers of the gate-driving circuit GDC (see, e.g., FIG. 3) described with reference to FIG. 3.

The second bridge portion 22 may have a serpentine shape. A length of the second bridge portion 22 may be greater than a minimum distance between the second island portions 21 adjacent to each other in the second direction (e.g., the y direction or the −y direction). In one or more embodiments, the second bridge portion 22 may have a shape approximately like the Greek letter “Ω” being convex in the first direction (e.g., the x direction or the −x direction). The second bridge portions 22 may be arranged between the second island portions 21 adjacent to each other, and may be spaced apart from each other.

The second bridge portions 22 between the second island portions 21 adjacent to each other may be spaced apart from each other due to a second opening portion CS2. Between the second island portions 21 adjacent to each other, the second opening portions CS2 and the second bridge portions 22 may be alternately arranged in the first direction (e.g., the x direction or the −x direction). The second opening portions CS2 may have a same shape. Two end portions of each of the second bridge portions 22 may be connected to the second island portions adjacent to each other, and a side of each of the second bridge portions 22 may be spaced apart from a side of the second island portions 21 adjacent to the second bridge portion 22 and/or a side of another second bridge portion 22 due to the second opening portion CS2.

Any one of second island portions 21 arranged in the first non-display area NDA1 may correspond to the first island portions 11 in a plurality of rows arranged in the display area DA. For example, any one of the second island portion 21 arranged in 1 the first non-display area NDA1 may correspond to the first island portions 11 arranged in an (i)^{th} row and the first island portions 11 arranged in an (i+1)^{th} row in the display area DA (where i is a positive number). Although FIG. 4A illustrates that a second island portion 21 corresponds to two rows of the first island portions 11, the disclosure is not limited thereto. In one or more other embodiments, any one of the second island portions 21 arranged in the first non-display area NDA1 may correspond n rows of the first island portions 11 arranged in the display area DA (where n is a positive number of three or more).

The non-display area NDA (e.g., the first non-display area NDA1) may include: a first sub-non-display area SNDA1, in which the second island portions 21 and the second bridge portions 22 are arranged; and a second sub-non-display area SNDA2 between the first sub-non-display area SNDA1 and the display area DA. Third bridge portions 23 to connect the display area DA and the first sub-non-display area SNDA1 may be arranged in the second sub-non-display area SNDA2. An end portion of the third bridge portion 23 may be connected to the second island portion 21 and/or the second bridge portion 22, and another end portion of the third bridge portion 23 may be connected to the first island portion 11 and/or the first bridge portion 12.

The third bridge portion 23 may have a serpentine shape. In one or more embodiments, a shape of the third bridge portion 23 may be different from shapes of the first bridge portion 12 and the second bridge portion 22. In one or more embodiments, as illustrated in FIG. 4A, the third bridge portion 23 may have a shape approximately like the letter “Ω” protruding in the second direction (e.g., the y direction or the −y direction). The third bridge portions 23 adjacent to each other and arranged in the second direction (e.g., the y direction or the −y direction) may have a symmetrical structure (e.g., one may be convex in the y direction, and another one may be convex in the −y direction). Third opening portions CS3 and fourth opening portions CS4 having different shapes may be repeatedly arranged between the third bridge portions. A width of the third bridge portion 23 may be different from a width of the first bridge portion 12 and a width of the second bridge portion 22. In one or more embodiments, the width of the third bridge portion 23 may be greater than the width of the first bridge portion 12 and less than the width of the second bridge portion 22.

FIG. 4A illustrates that the second island portion 21 and the second bridge portion 22 in the non-display area (e.g., the first non-display area NDA1) have shapes different from shapes of the first island portion 11 and the first bridge portion 12 in the display area DA. In one or more other embodiments, the second island portion 21 and the second bridge portion 22 in the non-display area NDA may have shapes identical or substantially identical to the shapes of the first island portion 11 and the first bridge portion 12 in the display area DA, respectively.

FIG. 4B is an enlarged plan view of the portion IV illustrated in FIG. 3 as a portion of the display device 1 according to one or more embodiments of the present disclosure.

Referring to FIG. 4B, in the display area, the display device 1 includes the first island portions 11 spaced apart from one another and the first bridge portions 12 spaced apart from one another by the first opening portion CS1 and each connecting the first island portions 11 adjacent to each other. A structure of the display area DA in FIG. 4B may be identical or substantially identical to a structure of the display area DA described above with reference to FIG. 4A.

The display device 1 may include the second island portions 21 and the second bridge portions 22 arranged in the non-display area (e.g., the first non-display area NDA1). In one or more embodiments, the second island portions 21 and the second bridge portions 22 may have shapes substantially identical to the shapes of the first island portions 11 and the first bridge portions 12.

The second island portions 21 may be spaced apart from one another in the first direction (e.g., the x direction or the −x direction) and the second direction (e.g., the y direction or the −y direction) in the non-display area NDA, e.g., the first non-display area NDA1. Each of the second bridge portions 22 may connect the second island portions 21 adjacent to each other. The second bridge portions 22 may be spaced apart from each other by the second opening portion CS2 between the second bridge portions 22.

The second opening portion CS2 may have a shape substantially identical to a shape of the first opening portion CS1. For example, the second opening portion CS2 having the shape approximately like the letter “H” and the second opening portion CS2 having the shape approximately like the letter “I” may be alternately and repeatedly arranged in the non-display area NDA (e.g., the first non-display area NDA1). Two end portions of each of the second bridge portions 22 may be connected to each of the second island portions 21 adjacent to the second bridge portion 22, and a side of each of the second bridge portions 22 may be spaced apart from a side of the second island portions 21 adjacent to the second bridge portion 22 and/or a side of another second bridge portion 22 by the second opening portion CS2.

Each of the second island portions 21 may be connected four of the second bridge portions 22. Each of the second island portions 21 may include the drivers of the gate-driving circuit GDC (see, e.g., FIG. 3) described with reference to FIG. 3.

The second island portions 21 in any one row arranged in the first non-display area NDA1 may correspond to the first island portions 11 in any one row arranged in the display area DA. For example, the second island portions 21 arranged in the (i)^{th} row in the first direction (e.g., the x direction or the −x direction) in the first non-display area NDA1 may correspond to the first island portions 11 arranged in a same row, e.g., the (i)^{th} row, in the display area DA (where i is a positive number).

The display device 1 may include the third bridge portions 23 arranged in the second sub-non-display area SNDA2 to connect the display device 1 and the first sub-non-display area SNDA1. The non-display area NDA (e.g., the first non-display area NDA1) may include: the first sub-non-display area SNDA1 in which the second island portions 21 and the second bridge portions 22 are arranged; and the second sub-non-display area SNDA2 including the third bridge portions 23 and located between the first sub-non-display area SNDA1 and the display area DA. The third bridge portion 23 may be substantially identical to the first bridge portion 12 and the second bridge portion 22. For example, the width of the third bridge portion 23 may be identical or substantially identical to the width of the first bridge portion 12 and the width of the second bridge portion 22.

FIG. 4C is an enlarged plan view of the portion IV illustrated in FIG. 3 as the portion of the display device 1 according to one or more embodiments of the present disclosure.

Referring to FIG. 4C, the display device 1 may include, in the display area DA, the first island portions 11 spaced apart from one another in the first direction (e.g., the x direction or the −x direction) and the second direction (e.g., the y direction or the −y direction) and the first bridge portions 12 connecting the first island portions 11 adjacent to each other.

The first bridge portions 12 may be spaced apart from each other by the first opening portion CS1 between the first bridge portions 12. The first bridge portion 12 may have a serpentine shape. For example, as illustrated in FIG. 4C, the first bridge portion 12 may have a shape approximately like the letter “S”.

Each of the first island portions 11 may be connected to the first bridge portions 12. For example, each of the first island portions 11 may be connected to four of the first bridge portions 12. Two of the first bridge portions 12 may be arranged at two sides of the first island portion 11 in the first direction (e.g., the x direction or the −x direction), and the other two of the first bridge portions 12 may be arranged at the other two sides of the first island portion 11 in the second direction (e.g., the y direction or the −y direction). Four of the first bridge portions 12 may be respectively connected to four sides of the first island portion 11. Four of the first bridge portions 12 may be respectively adjacent to corners of the first island portion 11.

In the non-display area NDA, e.g., the first non-display area NDA1 illustrated in FIG. 4C, the display device 1 may include the second island portions 21 spaced apart from one another in the first direction (e.g., the x direction or the −x direction) and the second direction (e.g., the y direction and the −y direction) and the second bridge portions 22 each connecting the second island portions 21 adjacent to each other.

The second bridge portions 22 may be spaced apart from each other by the second opening portion CS2 located between the second bridge portions 22. The second bridge portion 22 may have a serpentine shape. For example, as illustrated in FIG. 4C, the second bridge portion 22 may have a shape approximately like the letter “S”. A size and/or a width of the second bridge portion 22 may be different from a size and/or a width of the first bridge portion 12. For example, the size and/or the width of the second bridge portion 22 may be greater than the size and/or the width of the first bridge portion 12. A radius of curvature of a rounded portion of the second bridge portion 22 may be different from a radius of curvature of a rounded portion of the first bridge portion 12. For example, the radius of curvature of the rounded portion of the second bridge portion 22 may be greater than the radius of curvature of the rounded portion of the first bridge portion 12.

Each of the second island portions 21 may be connected to the second bridge portions 22. Each of the second island portions 21 may be connected four of the second bridge portions 22. Two of the second bridge portions 22 may be arranged at two sides of the second island portion 21 in the first direction (e.g., the x direction or the −x direction), and the other two of the second bridge portions 22 may be arranged at the other two sides of the second island portion 21 in the second direction (e.g., the y direction or the −y direction). In one or more embodiments, four of the second bridge portions 22 may be respectively connected to four sides of the second island portion 21. Each of the second bridge portions 22 may be connected to a center portion of each side of the second island portion 21.

The second island portions 21 in any one row arranged in the first non-display area NDA1 may correspond to the first island portions 11 in rows arranged in the display area DA. For example, the second island portions 21 in the any one row arranged in the first non-display area NDA1 may correspond to the first island portions 11 arranged in the (i)^{th} row and the first island portions 11 arranged in the (i+1)^{th} row in the display area DA (where i is a positive number). In one or more other embodiments, the second island portions 21 in any one row may correspond n rows of the first island portions 11 (where n is a positive number of 3 or more).

The non-display area NDA (e.g., the first non-display area NDA1) may include: the first sub-non-display area SNDA1 in which the second island portions 21 and the second bridge portions 22 are arranged; and the second sub-non-display area SNDA2 between the first sub-non-display area SNDA1 and the display area DA. The third bridge portions 23 to connect the display area DA and the first sub-non-display area SNDA1 may be arranged in the second sub-non-display area SNDA2. An end portion of the third bridge portion 23 may be connected to the second island portion 21, and another end portion of the third bridge portion 23 may be connected to the first island portion 11. For example, the end portion of the third bridge portion 23 may be connected to a center portion of a side of the second island portion 21, and the other end portion of the third bridge portion 23 may be connected to a center portion of a side of the first island portion 11.

The third bridge portion 23 may have a serpentine shape. In one or more embodiments, the shape of the third bridge portion 23 may be different from the shapes of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and smaller than the width of the second bridge portion 22. Third opening portions CS3 and fourth opening portions CS4 having different shapes may be alternately arranged in the second direction (e.g., the y direction or the −y direction) between the third bridge portions 23.

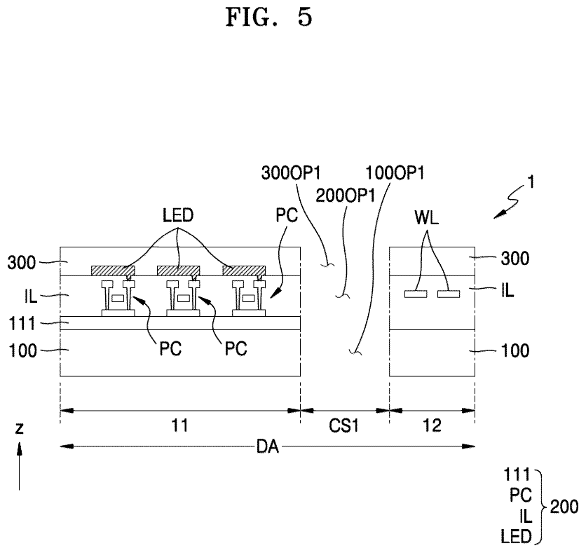

FIG. 5 is a cross-sectional view schematically illustrating the first island portion 11 and the first bridge portion 12 arranged in the display area DA of the display device 1 according to one or more embodiments of the present disclosure.

Referring to FIG. 5, the first island portion 11 and the first bridge portion 12 arranged in the display area DA may be spaced apart from each other with the first opening portion CS1 therebetween. The first island portion 11 includes light-emitting elements LED, and circuits electrically connected to the light-emitting elements LED and configured to drive the light-emitting elements LED (e.g., a pixel-driving circuit unit PC), and the first bridge portion 12 may include wirings WL electrically connected to the pixel-driving circuits PC arranged in each of the first island portions 11 adjacent to each other.

In the first island portion 11, a buffer layer 111 including an inorganic insulator is located on the substrate 100, and the pixel-driving circuit unit PC may be located on the buffer layer 111 (as used herein, “located on” may mean “above”). An insulating layer IL including an inorganic insulator and/or an organic insulator may be located between the pixel-driving circuit unit PC and the light-emitting element LED. The light-emitting element LED may be located on the insulating layer IL, and may be electrically connected to a corresponding pixel-driving circuit unit PC. The light-emitting elements LED may be configured to emit light having different colors or a same color. In one or more embodiments, the light-emitting elements LED may be configured to emit red, green, and blue light, respectively. In one or more other embodiments, the light-emitting elements LED may be configured to emit white light. In one or more other embodiments, the light-emitting elements LED may be configured to emit red, green, blue, and white light, respectively.

The substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. In one or more embodiments, the substrate 100 may include a single layer including the aforementioned polymer resins. In one or more other embodiments, the substrate 100 may have a multi-layer structure including: a base layer including the aforementioned polymer resin; and a barrier layer including an inorganic insulator. The substrate 100 including the polymer resin may be flexible, rollable, and/or bendable.

FIG. 5 illustrates three of the pixel-driving circuits PC arranged in each of the first island portions 11 and three light-emitting elements LED respectively connected to the pixel-driving circuit units PC according to one or more embodiments. However, the disclosure is not limited thereto. In one or more other embodiments, the number of pixel-driving circuits PC and the light-emitting elements LED arranged in the first island portion 11 may be one, two, or at least four.

An encapsulation layer 300 may be located on the light-emitting element LED and may protect the light-emitting element LED from an external force and/or permeation of moisture. The encapsulation layer 300 may include an inorganic encapsulation layer and/or an organic encapsulation layer. In one or more other embodiments, the encapsulation layer 300 may include a structure in which an inorganic encapsulation layer including an inorganic insulator, an organic encapsulation layer including an organic insulator, and an inorganic encapsulation layer including an inorganic insulator are stacked. In one or more other embodiments, the encapsulation layer 300 may include an organic material, such as a resin. In one or more other embodiments, the encapsulation layer 300 may include urethane epoxy acrylate. The encapsulation layer 300 may include a photosensitive material (e.g., a material such as a photoresist).

In the first bridge portion 12, the insulating layer IL including an organic insulator may be located on the substrate 100. When the display device 1 is stretched, unlike the first island portion 11, the first bridge portion 12 that is deformed to a relatively greater degree may not include a layer including an inorganic insulator in which cracks may occur.

In one or more embodiments, the substrate 100 corresponding to the first bridge portion 12 may have a stack structure identical or substantially identical to a stack structure of the substrate 100 corresponding to the first island portion 11. In one or more embodiments, the substrate 100 corresponding to the first bridge portion 12 and the substrate 100 corresponding to the first island portion 11 may include a polymer resin layer formed together in a same process. In one or more other embodiments, the substrate 100 corresponding to the first bridge portion 12 may have a stack structure different from the stack structure of the substrate 100 corresponding to the first island portion 11. In one or more other embodiments, the substrate 100 corresponding to the first bridge portion 12 may have a multi-layer structure including: a base layer including a polymer resin; and a barrier layer including an inorganic insulator, and the substrate 100 corresponding to the first bridge portion 12 may have a structure of a polymer resin layer, without a layer including an inorganic insulator.

As described above, the wirings WL of the first bridge portion 12 may include signal lines (e.g., a gate line, a data line, and/or the like) configured to provide electric signals or voltage lines (e.g., a driving voltage line, an initialization voltage line, and the like) configured to provide voltages to transistors included in the pixel-driving circuit unit PC of the first island portion 11. The encapsulation layer 300 may also be arranged in the first bridge portion 12. In one or more other embodiments, the encapsulation layer 300 may be not in the first bridge portion 12.

Referring to FIGS. 4A to 4C and 5, the substrate 100 corresponding to the first island portion 11 and the substrate 100 corresponding to the first bridge portion 12 may be connected to each other. In other words, the plan views illustrated above in FIGS. 4A to 4C may be substantially identical to the plan view of the substrate 100 illustrated in FIG. 5. In other words, the substrate 100 may include an area corresponding to the first island portion 11, and an area corresponding to the first bridge portion 12, and also may include or define an opening 100OP1 having a shape identical or substantially identical to the shape of the first opening portion CS1.

Similarly, the encapsulation layer 300 corresponding to the first island portion 11 and the encapsulation layer 300 corresponding to the first bridge portion 12 may be connected to each other. For example, the plan views illustrated above in FIGS. 4A to 4C may be substantially identical to the plan view of the encapsulation layer 300. In other words, the encapsulation layer 300 may include an area corresponding to the first island portion 11, an area corresponding to the first bridge portion 12, and an opening 300OP1 having a shape identical or substantially identical to the shape of the first opening portion CS1.

A circuit-light-emitting element layer 200 between the substrate 100 and the encapsulation layer 300 may include the buffer layer 111, the pixel-driving circuit unit PC, the wiring WL, the insulating layer IL, and the light-emitting element LED. Like the substrate 100, the plan views illustrated above in FIGS. 4A to 4C may be substantially identical to a plan view of the circuit-light-emitting element layer 200. In other words, the circuit-light-emitting element layer 200 may include an opening 200OP1 having a shape identical or substantially identical to the shape of the first opening portion CS1.

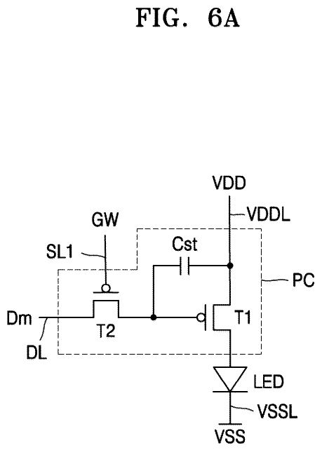

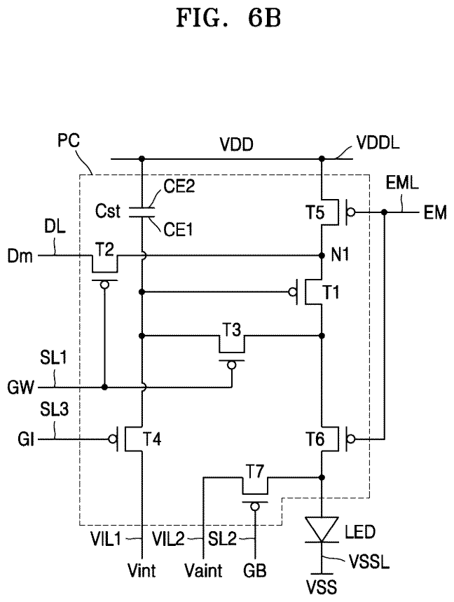

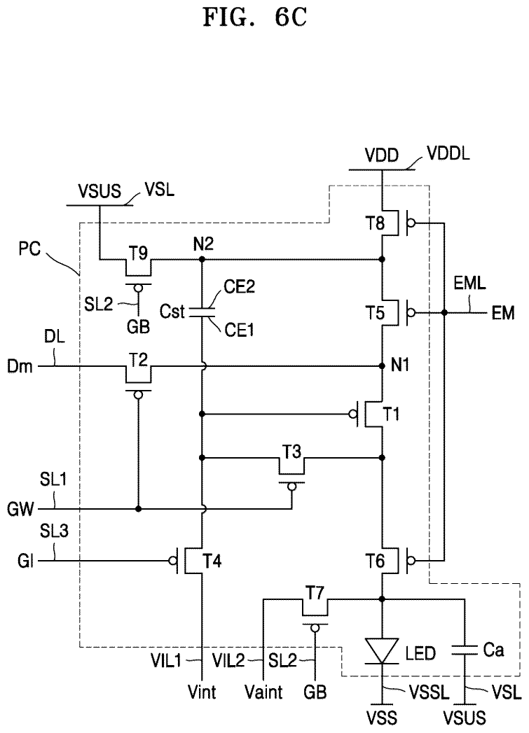

FIGS. 6A to 6C are each an equivalent circuit diagram of the subpixel of the display device 1 according to one or more embodiments of the present disclosure.

Referring to FIG. 6A, the light-emitting element LED corresponding to the subpixel may be electrically connected to the pixel-driving circuit unit PC, and the pixel-driving circuit unit PC may include a first transistor T1, a second transistor T2, and a storage capacitor Cst. The pixel-driving circuit PC may be electrically connected to the signal lines and the voltage lines. The signal lines may include a gate line (e.g., a first scan line SL1) and a data line DL, and the voltage lines may include a first voltage line VDDL.

The second transistor T2 may be electrically connected to the first scan line SL1 and the data line DL. The first scan line SL1 may be configured to provide a first scan signal GW to a gate electrode of the second transistor T2. The second transistor T2 may be configured to deliver a data signal Dm input from the data line DL to the first transistor T1, in response to the first scan signal GW input from the first scan line SL1.

The storage capacitor Cst may be electrically connected to the second transistor T2 and the first voltage line VDDL, and may be configured to store a voltage corresponding to a difference between a voltage delivered from the second transistor T2 and a first power voltage VDD provided by the first voltage line VDDL.

The first transistor T1, which is a driving transistor, may be configured to control a driving current flowing through the light-emitting element LED. The first transistor T1 may be connected to the first voltage line VDDL and the storage capacitor Cst. The first transistor T1 may be configured to, in response to a value of a voltage stored in the storage capacitor Cst, control the driving current flowing from the first voltage line VDDL through the light-emitting element LED. The light-emitting element LED may be configured to emit light having a luminance (e.g., a certain luminance) in response to the driving current. A first electrode of the light-emitting element LED may be electrically connected to the first transistor T1, and a second electrode of the light-emitting element LED may be electrically connected to a second voltage line VSSL configured to provide a second power voltage VSS.

Although FIG. 6A illustrates that the pixel-driving circuit unit PC includes two transistors and one storage capacitor, in one or more other embodiments, the pixel-driving circuit PC may include three or more transistors.

Referring to FIG. 6B, the pixel-driving circuit PC may include a first transistor T1, a second transistor T2, a third transistor T3, a fourth transistor T4, a fifth transistor T5, a sixth transistor T6, a seventh transistor T7, and a storage capacitor Cst.

The pixel-driving circuit unit PC may be electrically connected to the signal lines and the voltage lines. The signal lines may include gate lines. The gate lines may include a first scan line SL1, a second scan line SL2, a third scan line SL3, and an emission control line EML, and a data line DL. The voltage lines may include a first initialization voltage line VIL1, a second initialization voltage line VIL2, and the first voltage line VDDL.

The first voltage line VDDL may be configured to deliver the first power voltage VDD to the first transistor T1. The first initialization voltage line VIL1 may be configured to deliver a first initialization voltage Vint, which initializes the first transistor T1, to the pixel-driving circuit PC. The second initialization voltage line VIL2 may be configured to deliver a second initialization voltage Vaint, which initializes the first electrode of the light-emitting element LED, to the pixel-driving circuit PC.

The first transistor T1 may be electrically connected to the first voltage line VDDL via the fifth transistor T5, and may be electrically connected to the light-emitting element LED via the sixth transistor T6. The first transistor T1 is configured to function as the driving transistor, receive the data signal Dm in response to a switching operation of the second transistor T2, and provide the driving current to the light-emitting element LED.

The second transistor T2, which may be a data write transistor, may be electrically connected to the first scan line SL1 and the data line DL. The second transistor T2 may be electrically connected to the first voltage line VDDL via the fifth transistor T5. The second transistor T2 may be turned on in response to the first scan signal GW delivered through the first scan line SL1 and may perform a switching operation to deliver the data signal Dm, which is delivered from the data line DL, to the first node N1.

The third transistor T3 may be electrically connected to the first scan line SL1, and may be electrically connected to the light-emitting element LED via the sixth transistor T6. The third transistor T3 may be turned on in response to the first scan signal GW delivered through the first scan line SL1 and may have the first transistor T1 diode-connected.

The fourth transistor T4, which may be a first initialization transistor, may be electrically connected to the third scan line SL3 and the first initialization line VIL1. The fourth transistor T4 may be turned on in response to a third scan signal G1 delivered through the third scan line SL3, may deliver the first initialization voltage Vint from the first initialization voltage VIL1 to a gate electrode of the first transistor T1, and may initialize a voltage of the gate electrode of the first transistor T1. The third scan signal GI may correspond to a first scan signal of another pixel-driving circuit unit PC arranged in a previous row before a row including a corresponding pixel-driving circuit unit PC.

The fifth transistor T5 may include an operation control transistor, and the sixth transistor T6 may include an emission control transistor. The fifth transistor T5 and the sixth transistor T6 may be electrically connected the emission control line EML, may be concurrently (e.g., simultaneously or substantially simultaneously) turned on response to the emission control signal EM delivered through the emission control line EML, and may form a current path such that the driving current may flow in a direction from the first voltage line VDDL to the light-emitting element LED.

The seventh transistor T7, which may be a second initialization transistor, may be electrically connected to the second scan line SL2, the second initialization voltage line VIL2, and the sixth transistor T6. The seventh transistor T7 may be turned on in response to a second scan signal GB delivered through the second scan line SL2, and may initialize a first electrode of the light-emitting element LED by driving the second initialization voltage Vaint from the second initialization voltage line VIL2 to the first electrode of the light-emitting element LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may be configured maintain a voltage applied to the gate electrode of the first transistor T1 by storing and maintaining a voltage corresponding to a difference between voltages at two ends of the gate electrodes of each of the first voltage line VDDL and the first transistor T1.

Referring to FIG. 6C, the pixel-driving circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel-driving circuit unit PC may be electrically connected to the signal lines and the voltage lines. The signal lines may include gate lines. The gate lines may include, the first scan line SL1, a second scan line SL2, a third scan line SL3, and an emission control line EML, and the data line DL. The voltage lines may include the first initialization voltage line VIL1, the second initialization voltage line VIL2, a sustenance voltage line VSL, and the first voltage line VDDL.

The first voltage line VDDL may be configured to deliver the first power voltage VDD to the first transistor T1. The first initialization voltage line VIL1 may be configured to deliver a first initialization voltage Vint, which initializes the first transistor T1, to the pixel-driving circuit PC. The second initialization voltage line VIL2 may be configured to deliver the second initialization voltage Vaint, which initializes the first electrode of the light-emitting element LED, to the pixel-driving circuit PC. The sustenance voltage line VSL may be configured to provide a sustenance voltage VSUS to a second node N2 (e.g., the second electrode CE2 of the storage capacitor Cst) in an initialization period and a data write period.

The first transistor T1 may be electrically connected to the first voltage line VDDL via the fifth transistor T5 and the eighth transistor T8 and may be electrically connected to the light-emitting element LED via the sixth transistor T6. The first transistor T1 may serve as the driving transistor, and may be configured to receive the data signal Dm in response to the switching operation of the second transistor T2 and provide the driving current to the light-emitting element LED.

The second transistor T2 may be electrically connected to the first scan line SL1 and the data line DL, and also may be electrically connected to the first voltage line VDDL via the fifth transistor T5 and the eighth transistor T8. The second transistor T2 may be turned on in response to the first scan signal GW delivered through the first scan line SL1 and may perform the switching operation of delivering the data signal Dm, which is delivered from the data line DL, to the first node N1.

The third transistor T3 may be electrically connected to the first scan line SL1, and also may be electrically connected to the light-emitting element LED via the sixth transistor T6. The third transistor T3 may be configured to compensate for a threshold voltage of the first transistor T1 by being turned on in response to the first scan signal GW, which is delivered through the first scan signal SL1, and having the first transistor T1 diode-connected.

The fourth transistor T4 may be electrically connected to the third scan line SL3 and the first initialization voltage line VIL1 and may be turned on in response to the third scan signal GI delivered through the third scan line SL3. The fourth transistor T4 may deliver the first initialization voltage Vint from the first initialization voltage line VIL1 to the gate electrode of the first transistor T1, and thereby may initialize the voltage of the gate electrode of the first transistor T1. The third scan signal GI may correspond to the first scan signal of another pixel circuit PC arranged in the previous row before the row including the corresponding pixel-driving circuit unit PC.

The fifth transistor T5, the sixth transistor T6, and the eighth transistor T8 may be electrically connected to the emission control line EML, may be concurrently (e.g., simultaneously or substantially simultaneously) turned on in response to the emission control signal EM delivered through the emission control line EML, and may form a current path such that the driving current may flow in the direction from the first voltage line VDDL to the light-emitting element LED.

The seventh transistor T7, which may be the second initialization transistor, may be electrically connected to the second scan line SL2, the second initialization voltage line VIL2, and the sixth transistor T6. The seventh transistor T7 may be turned on in response to the second scan signal GB delivered through the second scan line, and may deliver the second initialization voltage Vaint from the second initialization voltage line VIL2 to the first electrode of the light-emitting element LED, to thereby initialize the first electrode of the light-emitting element LED.

The ninth transistor T9 may be electrically connected to the second scan line SL2, the second electrode CE2 of the storage capacitor Cst, and the sustenance voltage line VSL. The ninth transistor T9 may be turned on in response to the second scan signal GB delivered through the second scan signal SL2, and may deliver the sustenance voltage VSUS to the second node N2 (e.g., the second electrode CE2 of the storage capacitor Cst) in the initialization period and the data write period.

The eighth transistor T8 and the ninth transistor T9 may each be electrically connected to the second node N2 (e.g., the second electrode CE2 of the storage capacitor Cst). In one or more other embodiments, in the initialization period and the data write period, the eighth transistor T8 may be turned off and the ninth transistor T9 may be turned on, and in an emission period, the eighth transistor T8 may be turned on and the ninth transistor T9 may be turned off. In the initialization period and the data write period, as the sustenance voltage VSUS may be applied to the second node N2, the uniformity (e.g., long range uniformity (LRU)) of luminance of the display device 1 according to a voltage drop of the first voltage line VDDL may be improved.

The storage capacitor Cst may include the first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustenance voltage line VSL, and the first electrode of the light-emitting element LED. The auxiliary capacitor Ca may store and sustain a voltage corresponding to a difference between voltages of the first electrode of the light-emitting element LED and the sustenance voltage line VSL while the seventh transistor T7 and the ninth transistor T9 are turned on, to thereby prevent or substantially reduce the likelihood of a black luminance increasing when the sixth transistor T6 is turned off.

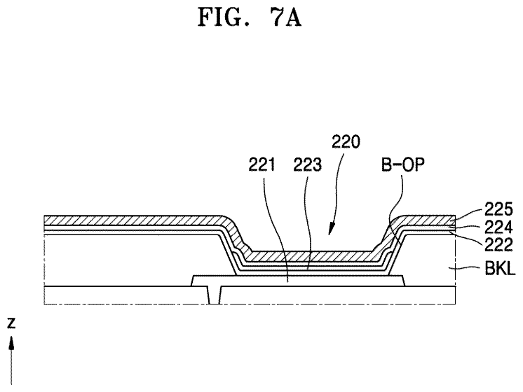

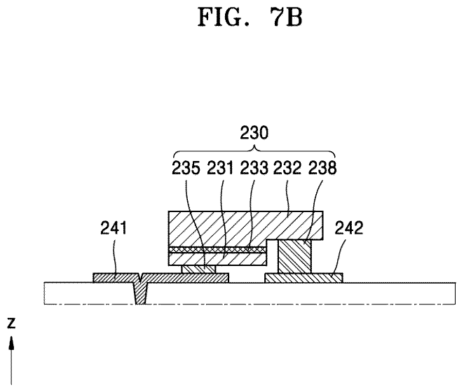

FIG. 7A is a cross-sectional view schematically illustrating the light-emitting element of the display device 1 according to one or more embodiments of the present disclosure.

Referring to FIG. 7A, the light-emitting element according to one or more embodiments may include an organic light-emitting diode 220 including an organic material. The organic light-emitting diode 220 may include a first electrode 221 located on an insulating layer, a second electrode 225 facing the first electrode 221, and a light-emitting layer 223 located between the first electrode 221 and the second electrode 225. A first function layer 222 may be located between the first electrode 221 and the light-emitting layer 223, and a second function layer 224 may be located between the light-emitting layer 223 and the second electrode 225.

An edge of the first electrode 221 may be covered by a bank layer BKL including an insulator. The bank layer BKL may include an opening B-OP overlapping with a center portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO), or the like. In one or more other embodiments, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. In one or more other embodiments, the first electrode 221 may further include a layer including ITO, IZO, ZnO, AZO, or In₂O₃ under/above the reflective layer mentioned above.

The light-emitting layer 223 may include a high-molecular weight organic material or a low-molecular weight organic material emitting light of corresponding colors. The first function layer 222 may include a hole transport layer (HTL) and/or a hole injection layer (HIL). The second function layer 224 may include an electron transport layer (ETL) and/or an electron injection layer (EIL).

The second electrode 225 may include a conductive material having a small work function. For example, the second electrode 225 may include a transparent (e.g., semitransparent) layer including Ag, Mg, Al, Pt, Pd, Au, Ni, Nd, Ir, Cr, Li, Ca, or alloys thereof. For example, the second electrode 225 may further include a layer including ITO, IZO, ZnO, AZO, or In₂O₃ on the transparent layer including the aforementioned materials.

FIG. 7B is a cross-sectional view schematically illustrating a light-emitting element LED of the display device 1 according to one or more embodiments of the present disclosure.

Referring to FIG. 7B, the light-emitting element LED according to one or more embodiments may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242 located on a same layer, respectively.

In one or more other embodiments, the first semiconductor layer 231 may include a p-type semiconductor layer. The p-type semiconductor layer may be selected from semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and may be doped with a p-type dopant, such as Mg, Zn, Ca, Sr, Ba, and/or the like.

The second semiconductor layer 232 may include, for example, a n-type semiconductor layer. The n-type semiconductor layer may be selected from among the semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and the like, and may be doped with the n-type dopant, such as Si, Ge, Sn, and/or the like.

An intermediate layer 233, which is an area in which electrons and holes are recombined, transitions to a lower energy level as the electrons and holes are recombined, and may generate light having a corresponding wavelength. The intermediate layer 233 may be formed by including a semiconductor material, such as a semiconductor material having a composition formula of InₓAl_{y}Ga_{1-x-y}N (0≤x≤1, 0≤y≤1, 0x+y≤1), and may be formed in a single quantum well structure or a multi-quantum well (MQW) structure. In addition, the intermediate layer 233 may also include a quantum wire structure or a quantum dot structure.

Although a case in which the first semiconductor layer 231 includes the p-type semiconductor layer and the second semiconductor layer 232 includes the n-type semiconductor layer is described with reference to FIG. 7B, the disclosure is not limited thereto. In one or more other embodiments, the first semiconductor layer 231 may include the n-type semiconductor layer, and the second semiconductor layer 232 may include the p-type electrode.

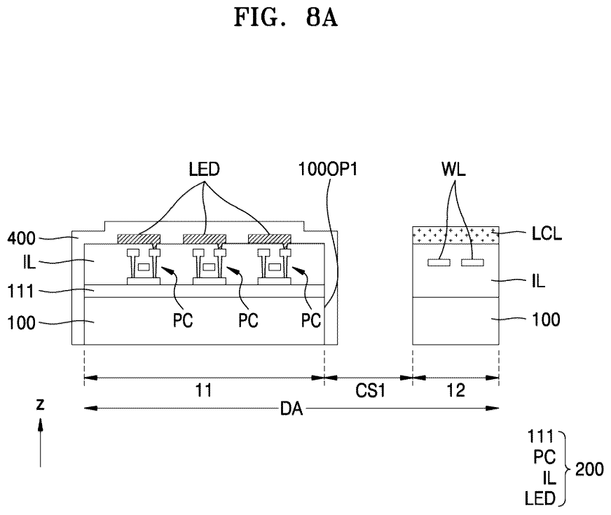

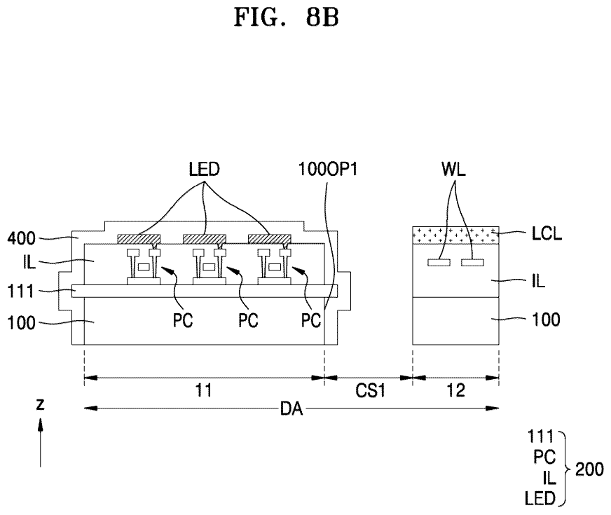

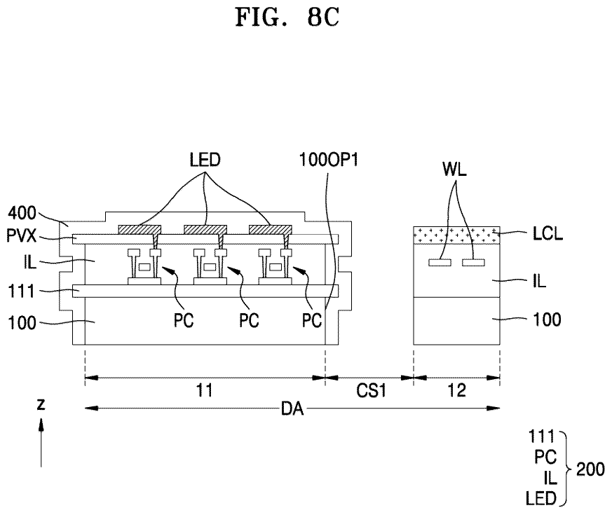

FIGS. 8A to 8C are cross-sectional views each schematically illustrating a portion of the display device 1 according to one or more embodiments of the present disclosure.

Referring to FIGS. 8A to 8C, the display device 1 may include the substrate 100, which includes the plurality of first island portions 11 spaced apart from one another, and the first bridge portions 12 connecting the plurality of first island portions 11, and which defines the opening 100OP1 located between the plurality of first island portions 11, the light-emitting element LED located on each of the plurality of first island portions 11, and a luminance compensation layer LCL located on each of the first bridge portions 12.

In the first island portion 11, the buffer layer 111 including the inorganic insulator may be located on the substrate 100, and the pixel-driving circuit unit PC may be located on the buffer layer 111 (as used herein, “located on” may mean “above”). The insulating layer IL including the inorganic insulator and/or the organic insulator may be located between the pixel-driving circuit unit PC and the light-emitting elements LED. The light-emitting elements LED may be located on the insulating layer IL, and may be electrically connected to a corresponding pixel-driving circuit PC.

In one or more other embodiments, as illustrated in FIG. 8B, an end of the buffer layer 111 may have a tip structure protruding outwardly, or extending further, as compared with an edge of the insulating layer IL.

In one or more other embodiments, as illustrated in FIG. 8C, an inorganic insulating layer PVX may be further located on the insulating layer IL. The light-emitting element LED may be located on the inorganic insulating layer PVX. For example, an end of the inorganic insulating layer PVX may have a tip structure protruding outwardly, or extending further, as compared with the edge of the insulating layer IL.

In the first bridge portion 12, the insulating layer IL including an organic insulator may be located on the substrate 100, and the luminance compensation layer LCL may be on the insulating layer IL. The luminance compensation layer LCL may be located only on the first bridge portion 12. That is, the luminance compensation layer LCL may be spaced apart from the first island portion 11. A reason for this may be that, when the display device 1 is deformed due to external stress, the first island portion 11 may be only minutely deformed due to the stress, and it may be substantially difficult to observe the effect of the luminance compensation layer LCL as a result of insufficient deformation of the first island portion 11.

In one or more embodiments, the luminance compensation layer LCL may include a color conversion material. The color conversion material may include a mechanochromism material. The mechanochromism material may change color in response to a stress being applied to a solid-phase chemical material due to mechanical grinding, crushing, milling, or the like. The luminance compensation layer LCL according to one or more embodiments may include a color conversion material that changes color in response to the stress, as described above. The luminance compensation layer LCL may include the color conversion material, and thus, may emit light when the first bridge portions 12 are deformed due to external stress. Accordingly, the first bridge portions 12 may compensate for degradation in the luminance of the first island portion 11 by supplementing the luminance of the first island portion 11 surrounded by the first bridge portions 12.

In one or more embodiments, the color conversion material may include a spyropyran compound (e.g., a spiropyran compound). The spyropyran compound may be clear, and may develop color when subjected to impacts, stress, or deformation.

In one or more embodiments, the spyropyran compound may be represented by [Formula 1] below.

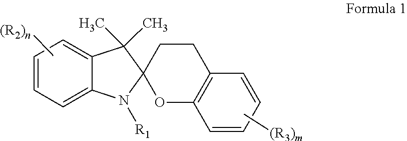

In the [Formula 1], R1 may be a substituted or unsubstituted alkyl group having 1 carbon atom to 20 carbon atoms, R2 and R3 may be each independently a hydrogen atom, a deuterium atom, a halogen atom, a nitro group, a substituted or unsubstituted oxy group, a substituted or unsubstituted alkyl group having 1 carbon atom to 20 carbon atoms, a substituted or unsubstituted aryl group having six or more but not more than thirty ring-forming carbon atoms, or a substituted or unsubstituted heteroaryl group having 2 ring-forming carbon atoms to 30 ring-forming carbon atoms. In addition, in [Formula 1], m and n may each be an integer from 0 to 4. If m is an integer of 2 or more, a plurality of R3s may be different or identical or substantially identical, and if n is an integer of 2 or more, a plurality of R2s may be different or identical or substantially identical.

The spyropyran compound may develop a corresponding color as a molecular structure thereof changes from an SP form not having color to an MC form due to stress, such as a force, stress, and deformation from outside. For example, in the [Formula 1], deep purple color may be developed when the molecular structure changes from the SP form to the MC form.

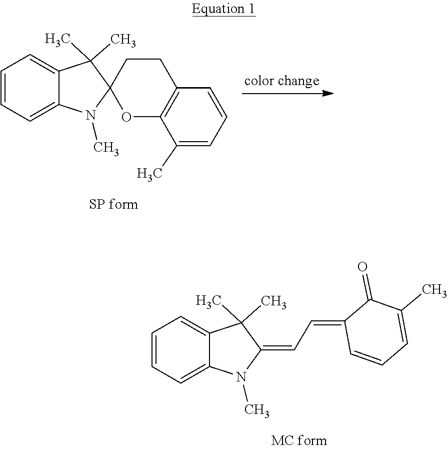 [SMILES: Cc1cccc2c1OC1(CC2)N(C)c2ccccc2C1(C)C ; CC1=CC=C/C(=C\C=C2\N(C)c3ccccc3C2(C)C)C1=O]

The color developed by the spyropyran compound may differ according to types of substituents. In one or more embodiments, at least one of red, green, or blue may be developed by the spyropyran compound. In [Formula 2] below, when the molecular structure changes from the SP form to the MC form, red color may be developed.

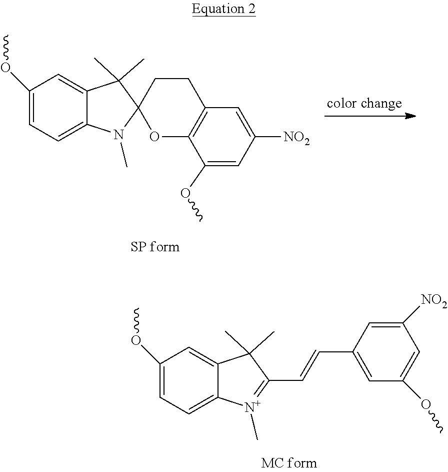

In one or more embodiments, the luminance of the luminance compensation layer LCL may increase according to an increase in the stress applied to the first bridge portions 12. That is, as more deformation occurs to the first bridge portions 12, the luminance of the luminance compensation layer LCL may accordingly increase. As described above, the color conversion material develops color as the molecular structure changes from the SP form to the MC form due to the external stress. As the external stress increases, more molecular structures of the SP form may be transformed into the MC form, and this may be expressed as the increase in the luminance of the luminance compensation layer LCL.

In one or more embodiments, the luminance compensation layer LCL may further include a base resin in addition to the color conversion material. The base resin may give elasticity to the luminance compensation layer LCL, and by doing so, may prevent or substantially reduce the generation of cracks and the like in the deformation of the first bridge portions 12. For example, the base resin may include at least one of polymethylmethacrylate (PMMA), polyurethane (PU), polydimethylsiloxane (PDMS), polyimide (PI), styrene-ethylene-butylene-styrene (SEBS), polymethylacrylate, polyacrylate (PA), polyacrylonitrile, polycaprolactone, polysulfone, polyaniline, polystyrene (PS), polybutylacrylate, epoxy, or silicon.

As the spyropyran compound develops color due to change in the molecular structure caused by the external stress, the change of the molecular structure may be irreversible. That is, the molecular structure of the MC form transformed due to the stress applied to the spyropyran compound may not be transformed into the molecular structure of the SP form on its own. In other words, after the color is developed in the luminance compensation layer LCL due to the stress applied to the first bridge portions 12, even when the stress applied to the first bridge portions 12 is removed, the luminance compensation layer LCL may maintain the color that is previously developed. Therefore, in one or more embodiments, a process such as recovering the transformed molecular structure may be performed by further arranging a component (e.g., a UV projector) on the luminance compensation layer LCL.

The display device according to one or more embodiments may include a protective layer 400 covering each of the first island portions 11. The protective layer 400 may be provided to encapsulate the light-emitting element LED located on the first island portion 11. By encapsulating the light-emitting element LED, the protective layer 400 may protect the light-emitting element LED from an external force or external air, such as moisture. The protective layer 400 may be arranged in each of the first island portions 11 and individually encapsulate each of the first island portions 11. In one or more other embodiments, the encapsulation layer 300 described above with reference to FIG. 5 may be further located on the protective layer 400.

In one or more embodiments, the protective layer 400 may include an inorganic insulator. For example, when the protective layer 400 includes the inorganic insulator, the protective layer 400 may include silicon oxide, silicon nitride, silicon oxynitride, or the like.

The protective layer 400 may cover the light-emitting element LED, and may extend in a direction of the substrate 100 (e.g., the −z direction) to encapsulate an entire area of the first island portions 11. Accordingly, the protective layer 400 may cover all of the insulating layer IL and side surfaces of the substrate 100, thus may prevent or substantially reduce foreign air permeating through the insulating layer IL and the side surfaces of the substrate 100.

In one or more embodiments, the protective layer 400 may not be arranged in the first bridge portion 12. As described above, the protective layer 400 is formed to include the inorganic insulator, therefore it may be suitable not to arrange the protective layer 400 in the first bridge portion 12 deformed by the stress, considering the possibility of damage due to cracks and the like.

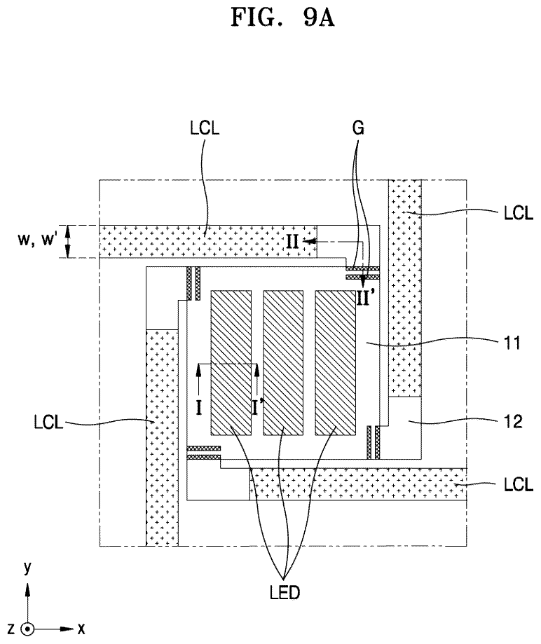

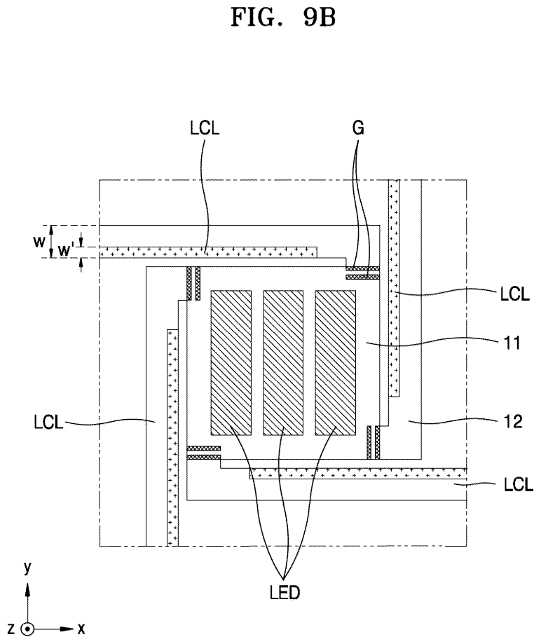

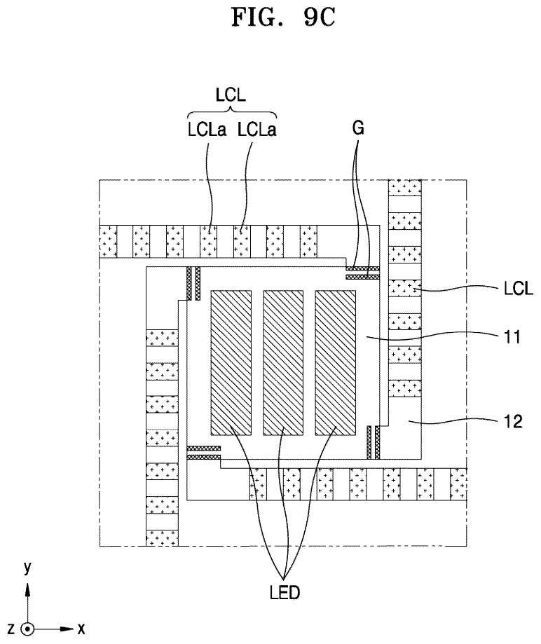

FIGS. 9A to 9C are plan views each schematically illustrating a portion of the display device 1 according to one or more embodiments of the present disclosure.

Referring to FIGS. 9A to 9C, the display device 1 according to one or more embodiments may include each of the first bridge portions 12 connected to the first island portion 11, and the luminance compensation layer LCL may be located on each of the first bridge portions 12.

The light-emitting element LED corresponding to the subpixel may be located on the first island portion 11. A plurality of the light-emitting elements LED may be located on the first island portion 11. FIGS. 9A to 9C illustrate that three light-emitting elements ELD are located on the first island portion 11. The light-emitting elements LED may emit light having a same color, and may also emit light having different colors (e.g., different respective colors).

In one or more embodiments, the luminance compensation layer LCL may be located in various suitable forms on each of the first bridge portions 12. Referring to FIG. 9A, the luminance compensation layer LCL may be arranged to cover an entire area of the first bridge portion 12. That is, a width w′ of the luminance compensation layer LCL may be the same or substantially the same as a width w of the first bridge portion 12.

In one or more other embodiments, as illustrated in FIG. 9B, the luminance compensation layer LCL may be arranged to cover a portion of the first bridge portion 12. That is, the width w′ of the luminance compensation layer LCL may be less than the width w of the first bridge portion 12. For example, the luminance compensation layer LCL may be arranged in a portion of the first bridge portion 12 adjacent to the first island portion 11. When the display device 1 is deformed due to external force, the portion of the first bridge portion 12 adjacent to the first island portion 11 may be an area to which more stress is concentrated compared with a portion of the first bridge portion 12 that is relatively less adjacent to the first island portion 11. Accordingly, by arranging the luminance compensation layer LCL in the portion of the first bridge portion 12 adjacent to the first island portion 11, the efficiency of the luminance compensation layer LCL according to the increase in the strength may be improved.

In one or more other embodiments, as illustrated in FIG. 9C, the luminance compensation layer LCL may have the form of a slit (e.g., may include or define gaps or slits) including the plurality of sub-luminance compensation layers LCLa. The plurality of sub-luminance compensation layers LCLa may be arranged spaced apart from each other at a corresponding interval. A width and the number of the plurality of sub-luminance compensation layers LCLa may be variously modified. As such, a shape and an area of the luminance compensation layer LCL may be variously modified according to embodiments, and by doing so, the luminance of the luminance compensation layer LCL may be controlled.

In addition, at least one groove G may be located between the first island portion 11 and each of the first bridge portions 12, which are connected to the first island portion 11. In a portion where the first island portion 11 and each of the first bridge portions 12 are connected, the groove G may reduce or prevent propagation of the cracks or permeation of external air toward the first island portion 11 through each of the first bridge portions 12.

The luminance compensation layer LCL may generally cover the first bridge portion 12, and may not overlap the groove G. In other words, an end of the luminance compensation layer LCL may be spaced apart from the groove G at a corresponding interval. The luminance compensation layer LCL may not overlap the groove G, and thus may be arranged so that the luminance compensation layer LCL and the first island portion 11 do not influence each other. The descriptions may also be applied to the embodiments described in FIGS. 9B and 9C.

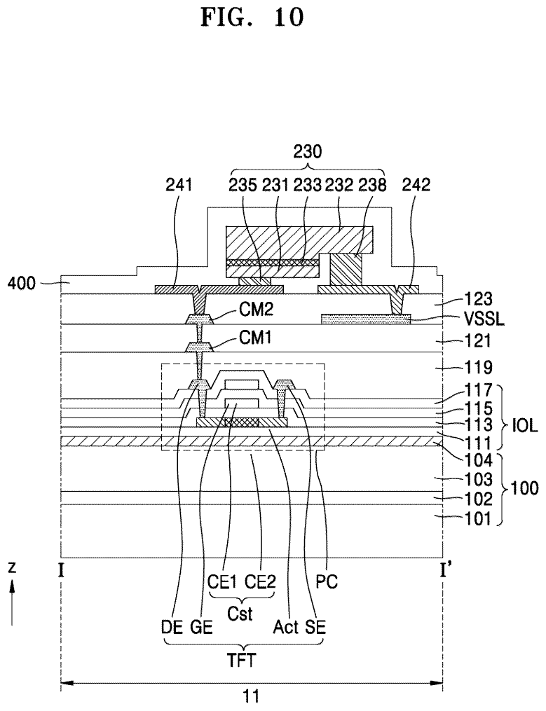

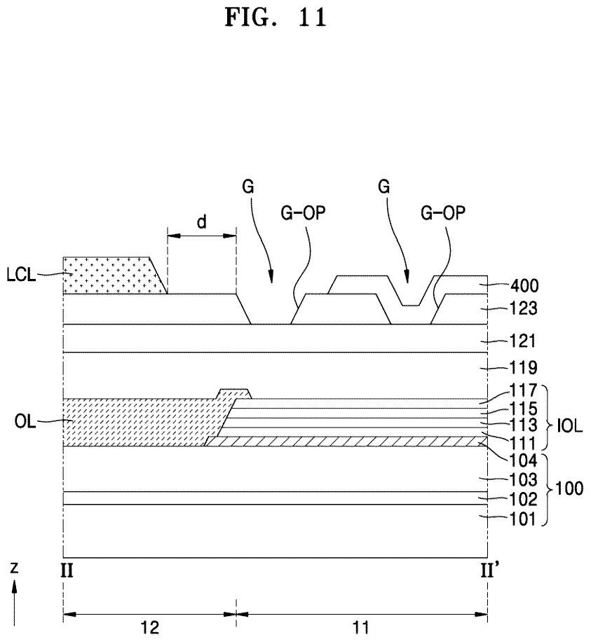

FIGS. 10 to 11 are plan views schematically illustrating a portion of a display device according to one or more embodiments of the present disclosure. FIG. 10 may correspond to a cross-section taken along the line I-I′ in FIG. 9A. FIG. 11 may correspond to a cross-section taken along the line II-II′ in FIG. 9A.

Referring to FIG. 10, the substrate 100 corresponding to the first island portion 11 may include a first base layer 101, a first barrier layer 102, a second base layer 103, and a second barrier layer 104. The first base layer 101 and the second base layer 103 may each include a polymer resin, such as polyether sulfone, polyarylate, polyetherimide, polyethylene naphthalate, polyethylene terephthalate, polyphenylene sulfide, polyimide, polycarbonate, cellulose triacetate, cellulose acetate propionate, and/or the like. The first barrier layer 102 and the second barrier layer 104 may each include an inorganic insulator, such as silicon oxide, silicon nitride, silicon oxynitride, and/or the like.

A size or an area of the inorganic insulating layer located on an uppermost layer of the substrate 100 (e.g., a size or an area of the second barrier layer 104) may be less than a size or an area of the first island portion 11 illustrated in FIG. 9A. Referring to FIG. 10, the size or the area of the inorganic insulating layer located on the uppermost layer of the substrate 100 (e.g., the size or the area of the second barrier layer 104) may be equal to or less than a size or an area of the first base layer 101, the first barrier layer 102, and/or the second base layer 103 of the substrate 100 corresponding to the first island portion 11.

The buffer layer 111 may be located on the substrate 100, and the pixel-driving circuit unit PC may be located on the buffer layer 111. The buffer layer 111 may include an inorganic insulator, such as silicon oxide, silicon nitride, silicon oxynitride, or the like.

A thin-film transistor TFT may include a semiconductor layer Act, a gate electrode GE, a source electrode SE, and a drain electrode DE. Although FIG. 10 illustrates a top gate type in which the gate electrode GE is located on the semiconductor layer Act with a gate-insulating layer 113 therebetween, according to one or more other embodiments, the thin-film transistor TFT may include a bottom gate type thin-film transistor.

The semiconductor layer Act may include polysilicon. For example, the semiconductor layer Act may include amorphous silicon, an oxide semiconductor, an organic semiconductor, or the like. The gate electrode GE may include a low-resistance metal material. The gate electrode GE may include a conductive material including molybdenum (Mo), Al, copper (Cu), titanium (Ti), and/or the like, and may be formed into multiple layers or a single layer including the aforementioned materials.

The gate electrode GE between the semiconductor layer Act and the gate electrode GE may include an inorganic insulator, such as silicon oxide, silicon nitride, silicon oxynitride, aluminum oxide, and/or titanium oxide. The gate-insulating layer 113 may include a single layer or multiple layers including the aforementioned materials.

The source electrode SE and the drain electrode DE may be on a same layer (e.g., a second interlayer insulating layer 117), and may include a same material. The source electrode SE and the drain electrode DE may include highly conductive materials. The source electrode SE and the drain electrode DE may include a conductive material including Mo, Al, Cu, Ti, and/or the like, and may be formed into multiple layers or a single layer including the aforementioned materials. In one or more embodiments, the source electrode SE and the drain electrode DE may be formed into a multi-layer structure including a titanium layer, an aluminum layer, and a titanium layer (Ti/Al/Ti). The second interlayer insulating layer 117 may include an inorganic insulator, such as silicon oxide, silicon nitride, silicon oxynitride, aluminum oxide, and/or titanium oxide, and may include a single layer or multiple layers including the aforementioned materials.

The storage capacitor Cst may include the first electrode CE1 and the second electrode CE2 overlapping with each other with a first interlayer insulating layer 115 therebetween. The storage capacitor Cst may overlap with the thin-film transistor TFT. Regarding this, FIG. 10 illustrates that the gate electrode GE of the thin-film transistor TFT is the first electrode CE1 of the storage capacitor Cst. In one or more other embodiments, the storage capacitor Cst may not overlap with the thin-film transistor TFT. The storage capacitor Cst may be covered by a second interlayer insulating layer 207. The second electrode CE2 of the storage capacitor Cst may include a conductive material including Mo, Al, Cu, Ti, and the like, and may include multiple layers or a single layer including the aforementioned materials. The first interlayer insulating layer 115 may be located between the gate-insulating layer 113 and the second interlayer insulating layer 117. The first interlayer insulating layer 115 may include an inorganic insulator, such as silicon oxide, silicon nitride, silicon oxynitride, aluminum oxide, and/or titanium oxide, and may include a single layer or multiple layers including the aforementioned materials.

A first organic insulating layer 119 may be located on the second interlayer insulating layer 117, and a second organic insulating layer 121 may be located on the first organic insulating layer 119. The first organic insulating layer 119 and the second organic insulating layer 121 may each include an organic insulator, such as polyimide.

A second voltage line VSSL may be located on the second organic insulating layer 121, and a third organic insulating layer 123 may be located on the second organic insulating layer 121. The third organic insulating layer 123 may include an organic insulator, such as polyimide. The second voltage line VSSL may include a conductive material including Mo, Al, Cu, Ti, and the like, and may be formed into multiple layers or a single layer including the aforementioned materials.

The first electrode pad 241 and the second electrode pad 242 may be located on the third organic insulating layer 123. The first electrode pad 241 may be electrically connected to the thin-film transistor TFT through a first connection metal CM1 between the first organic insulating layer 119 and the second organic insulating layer 121 and through a second connection metal CM2 between the second organic insulating layer 121 and the third organic insulating layer 123. The inorganic light-emitting diode 230 on the first electrode pad 241 and the second electrode pad 242 are as described above with reference to FIG. 7B. A light-emitting diode (e.g., the inorganic light-emitting diode 230) may be protected by the protective layer 400. In one or more embodiments, the encapsulation layer 300 described with reference to FIG. 5 may be further located on the protective layer 400. The encapsulation layer 300 may include an inorganic encapsulation layer and/or an organic encapsulation layer, or may include an organic material such as a resin. Although FIG. 10 illustrates a case in which the light-emitting diode is the inorganic light-emitting diode 230 described with reference to FIG. 7B, in one or more other embodiments, the light-emitting diode may include the organic light-emitting diode 220 described with reference to FIG. 7A.

Referring to FIG. 11, at least one groove G may be arranged on the substrate 100. FIG. 11 illustrates a structure in which two grooves G are arranged apart at a corresponding interval. In one or more embodiments, the groove G may be provided through an opening G-OP obtained by removing a portion of the third organic insulating layer 123. In one or more other embodiments, the opening G-OP of the groove G may extend in the direction of the substrate 100 (e.g., the −z direction), and in this case, a portion of the second organic insulating layer 121 under the third organic insulating layer 123 may be further removed. In one or more other embodiments, a metal layer or an inorganic layer may be further arranged on a bottom surface of the groove G (e.g., a bottom surface of the opening G-OP).

An inorganic insulator layer IOL may partially extend to overlap with the groove G. In one or more other embodiments, the inorganic insulator layer IOL may not be under the grooves G, or may be only under some of the grooves G.

An edge of the inorganic insulator layer IOL may be covered by an organic material layer OL. The organic material layer OL may include an opening corresponding to a center portion of the first island portion 11, and may have a shape of a frame extending along an edge of the first island portion 11. A portion of the organic material layer OL may extend toward the first bridge portion 12. The organic material layer OL may include an organic insulator, such as polyimide.

The luminance compensation layer LCL may be arranged not to overlap with the groove G. The luminance compensation layer LCL may be a distance d from the groove G.

A portion of the protective layer 400 may extend to a portion at which the groove G is located. That is, the protective layer 400 may overlap with the groove G in some areas. However, even in this case, the protective layer 400 may not extend to the first bridge portion 12 via the groove G. This is because, when the protective layer 400 extends to the first bridge portion 12, cracks may occur in the protective layer 400 due to deformation of the first bridge portion 12.

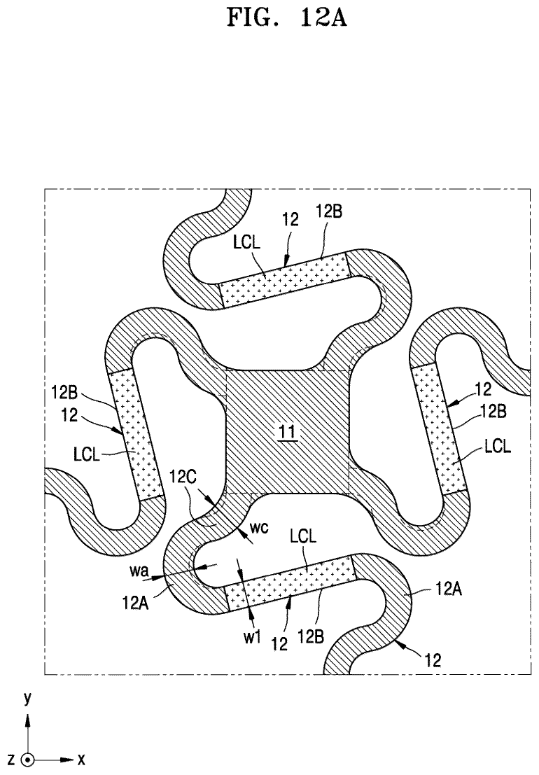

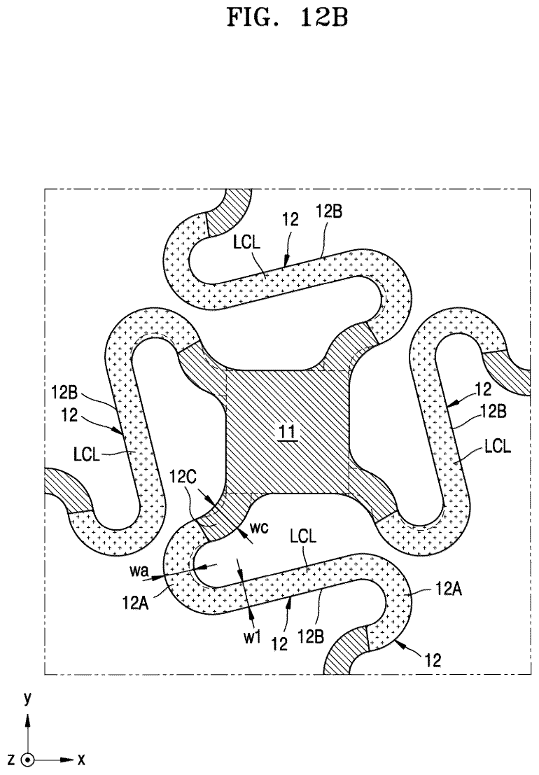

FIGS. 12A and 12B are plan views schematically illustrating a portion of the display device according to one or more embodiments of the present disclosure.

Embodiments in FIGS. 12A and 12B may correspond to a structure described with reference to FIG. 4C. First, referring to FIG. 12A, a portion of the first bridge portion 12 may have a different width. For example, a straight-line portion 12B of the first bridge portion 12 may have a first width w1, and a width wa of a first round portion 12A and/or a width wc of a second round portion 12C may be different from the first width w1 of the straight-line portion 12B. For example, the width wa of the first round portion 12A or the width wc of the second round portion 12C of the first bridge portion 12 may be greater than the first width w1 of the straight-line portion 12B.

Two sides of the first bridge portion 12 connected to the first island portion 11 may be smoothly connected respectively to sides of the first island portions 11 adjacent to each other.

As illustrated in FIG. 12A, the luminance compensation layer LCL may be arranged in the straight-line portion 12B of the first bridge portion 12 having a shape approximately like the letter ‘S’. However, the disclosure is not limited thereto, and as illustrated in FIG. 12B, the luminance compensation layer LCL may extend to the first round portion 12A and the second round portion 12C of the first bridge portion 12. In one or more other embodiments, the luminance compensation layer LCL may be variously modified in a suitable manner. For example, the luminance compensation layer LCL may be arranged only in the first round portion 12A and the second round portion 12C of the first bridge portion 12. For example, when stress is applied to the first bridge portion 12, relatively greater stress may be applied to the first round portion 12A and the second round portion 12C compared with the straight-line portion 12B, and thus, the efficiency of the luminance compensation layer LCL may be improved.

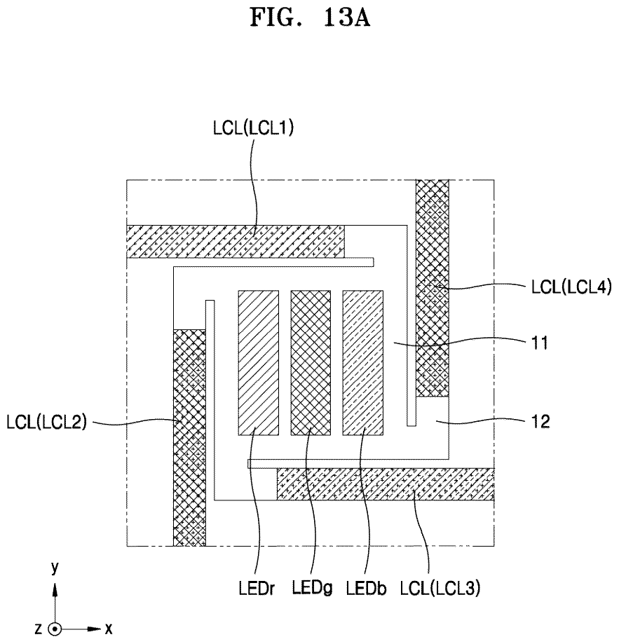

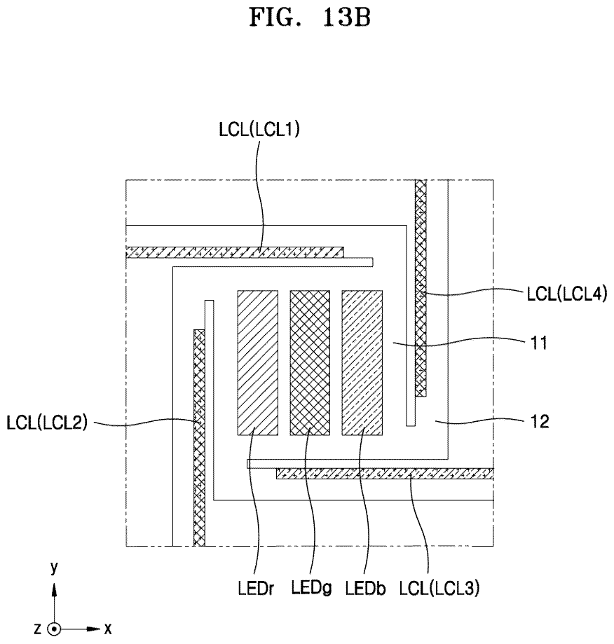

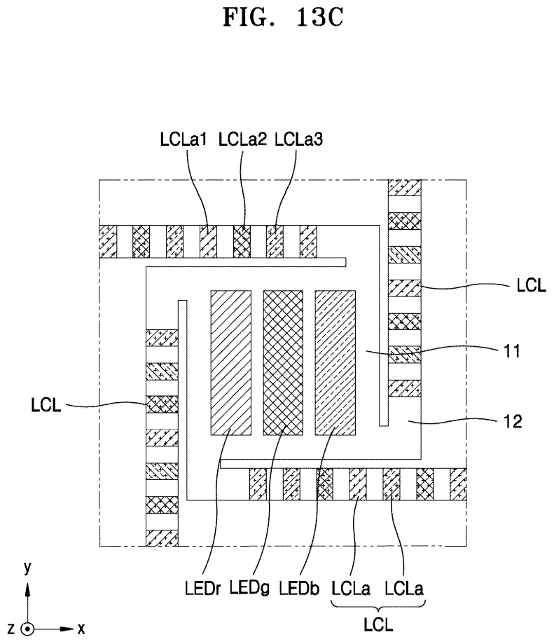

FIGS. 13A to 13C are plan views each schematically illustrating a portion of the display device 1 according to one or more embodiments of the present disclosure.

Referring to FIGS. 13A to 13C, the display device 1 according to one or more embodiments may include the first bridge portions 12 each connected to the first island portion 11, and the luminance compensation layer LCL may be located on each of the first bridge portions 12. One or more embodiments in FIG. 13A may have a structure identical or substantially identical to the structure of the embodiment described above with reference to FIG. 9A, one or more embodiments in FIG. 13B may have a structure identical or substantially identical to the structure of the one or more embodiments described above with reference to FIG. 9B, and one or more embodiments in FIG. 13C may have a structure identical or substantially identical to the structure described above with reference to FIG. 9C.

A first light-emitting element LEDr, a second light-emitting element LEDg, and a third light-emitting element LEDb, corresponding to the subpixels, may be located on the first island portion 11. For example, the first light-emitting element LEDr may emit light having a red wavelength, the second light-emitting element LEDg may emit light having a green wavelength, and the third light-emitting element LEDb may emit light having a blue wavelength. In one or more embodiments, the first light-emitting element LEDr, the second light-emitting element LEDg, and the third light-emitting element LEDb may all emit light of a same color. That is, the first light-emitting element LEDr, the second light-emitting element LEDg, and the third light-emitting element LEDb may all emit light having a red wavelength, or all may emit light having a green wavelength, or all may emit light having a blue wavelength.

The luminance compensation layer LCL may include a color conversion material that changes color in response to the stress, and may control a bandgap and colors to be converted by modifying a substituent (or an end group) of the color conversion material.

In one or more embodiments, a first luminance compensation layer LCL1, a second luminance compensation layer LCL2, a third luminance compensation layer LCL3, and a fourth luminance compensation layer LCL4 may be on each of the first bridge portions 12 connected to the first island portion 11. The first luminance compensation layer LCL1, the second luminance compensation layer LCL2, the third luminance compensation layer LCL3, and the fourth luminance layer LCL4 may express the same color, or may express different colors from each other. For example, when a same color is expressed by the first luminance compensation layer LCL1, the second luminance compensation layer LCL2, the third luminance compensation layer LCL3, and the fourth luminance compensation layer LCL4, the first luminance compensation layer LCL1, the second luminance compensation layer LCL2, the third luminance compensation layer LCL3, and the fourth luminance compensation layer LCL4 may all express red color, or may all express green color, or may all express blue color. In other words, the first to fourth luminance compensation layers LCL1 to LCL4 may all express a same color, and the color may be one of red, green, blue, or the like. For example, different colors may be expressed by the first luminance compensation layer LCL1, the second luminance compensation layer LCL2, the third luminance compensation layer LCL3, and the fourth luminance compensation layer LCL1. For example, the first luminance compensation layer LCL1 may express red color, the second luminance compensation layer LCL2 and the fourth luminance compensation layer LCL4 may express green color, and the third luminance compensation layer LCL3 may express blue color. However, the disclosure is not limited, and the embodiments may be variously modified in a suitable manner. The embodiments described above may also be applied to the first luminance compensation layer LCL1, the second luminance compensation layer LCL2, the third luminance compensation layer LCL3, and the fourth luminance compensation layer LCL4 corresponding to the one or more embodiments of FIG. 13B.

Referring to FIG. 13C, the luminance compensation layer LCL may have the form of a slit (e.g., may include slits or gaps) including a plurality of sub-luminance compensation layers LCLa. In one or more embodiments, the sub-luminance compensation layers LCLa may express a same color, or may respectively express different colors. For example, when the plurality of sub-luminance compensation layers LCLa express a same color, the plurality of sub-luminance compensation layers LCLa may all express red color, may all express green color, or may all express blue color. For example, when the plurality of sub-luminance compensation layers LCLa respectively express different colors, a first sub-luminance compensation layer LCLa1 may express red color, a second sub-luminance compensation layer LCLa2 adjacent to the first sub-luminance compensation layer LCLa1 may express green color, a the third sub-luminance compensation layer LCLa3 adjacent to the second sub-luminance compensation layer LCLa2 may express blue color. However, the disclosure is not limited and may be variously modified.

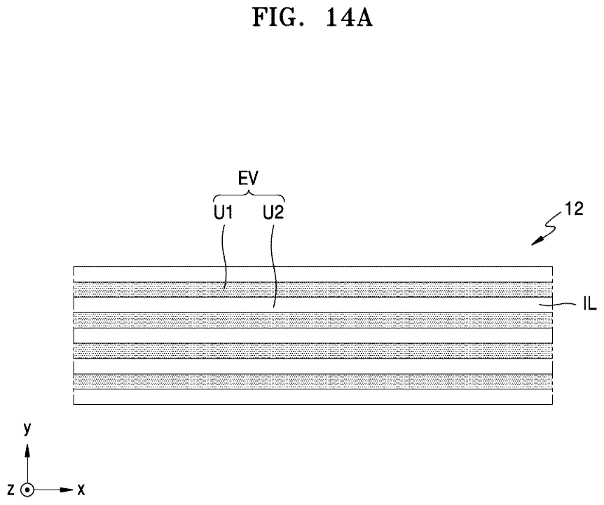

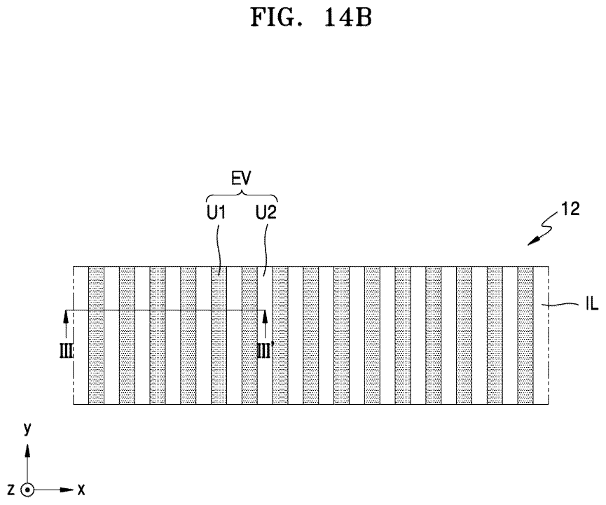

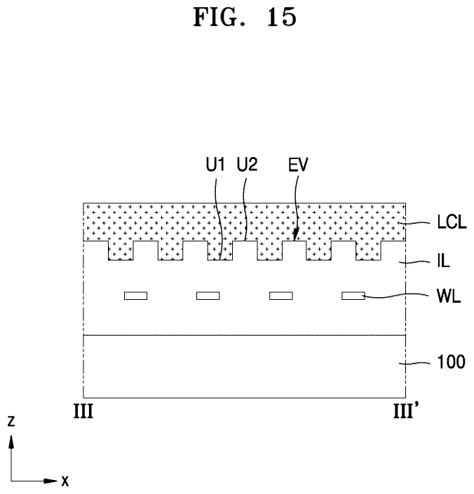

FIGS. 14A and 14B are plan views each schematically illustrating a portion of the display device according to one or more embodiments of the present disclosure. FIG. 15 is a cross-sectional view of the display device taken along the line III-III′ illustrated in FIG. 14B;

FIGS. 14A and 14B are enlarged plan views of the first bridge portion 12 according to one or more embodiments of the present disclosure. A concavo-convex structure EV may be provided on a top surface of the insulating layer IL in the first bridge portion 12. For example, a concave portion U1 and a convex portion U2 may be alternately provided on the top surface of the insulating layer IL, and may form the concavo-convex structure EV as illustrated in FIG. 15. The concave portion U1 and the convex portion U2 may have a structure extending in the first direction (e.g., the x direction and/or the −x direction), as illustrated in FIG. 14A. For example, the concave portion U1 and the convex portion U2 may have a structure extending in the second direction (e.g., the y direction and/or the −y direction), as illustrated in FIG. 14B. In one or more other embodiments, the concave portion U1 and the convex portion U2 may also have a structure extending in the third direction (e.g., a direction diagonal to the x direction and the y direction) crossing the first direction and the second direction.

Referring to FIG. 15, the luminance compensation layer LCL may be located right on the top surface of the insulating layer IL, on which the concavo-convex structure EV is provided. As the concavo-convex structure EV is formed on the top surface of the insulating layer, stress concentration on the top surface of the insulating layer IL may be improved compared with a structure in which the top surface of the insulating layer IL is provided in an even shape. The luminance compensation layer LCL may be located on the top surface of the insulating layer IL having increased roughness, and may improve sensitivity to discoloration of the machine.

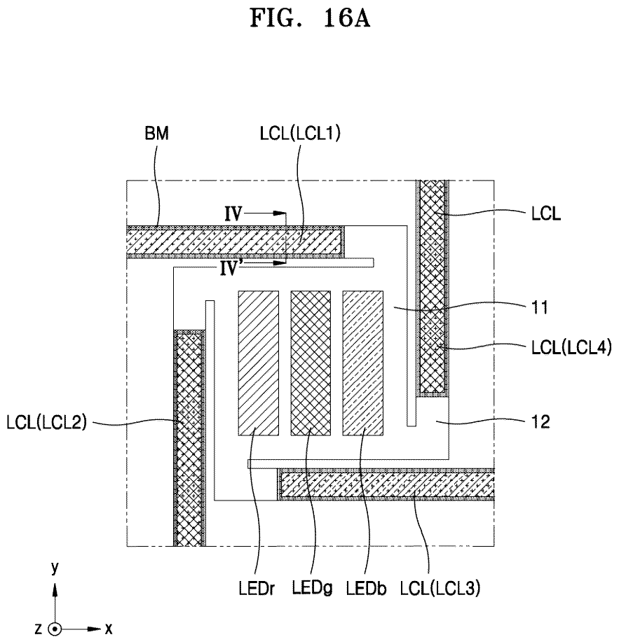

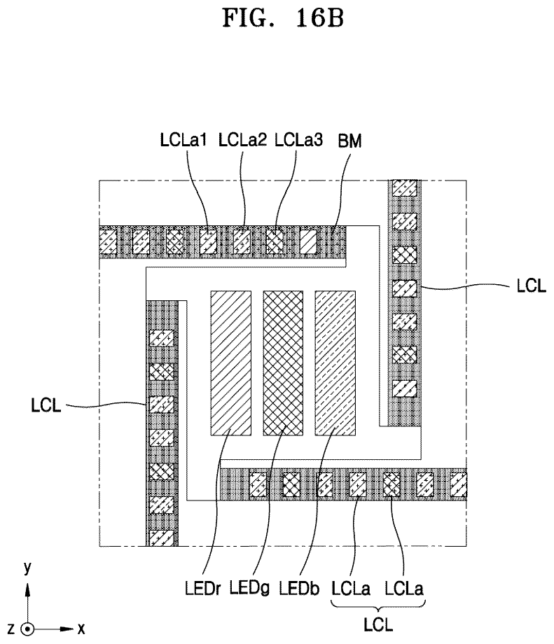

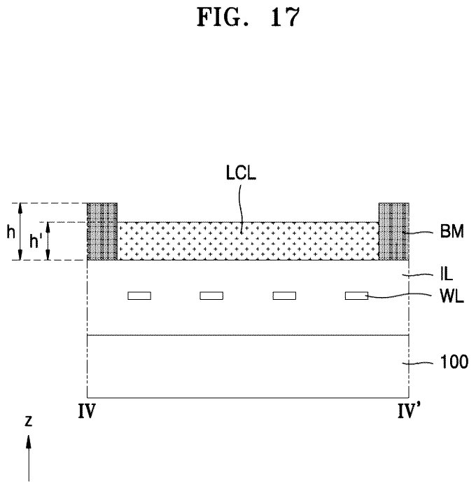

FIGS. 16A to 16B are plan views schematically illustrating a portion of the display device according to one or more embodiments of the present disclosure. FIG. 17 is a cross-sectional view of the display device taken along the line IV-IV′ illustrated in FIG. 16A.

Referring to FIGS. 16A, 16B, and 17, a light-blocking layer BM may be arranged at the edge of the first bridge portion 12 to surround a periphery of the luminance compensation layer LCL. The light-blocking layer BM may have a shape of a frame surrounding the periphery of the luminance compensation layer LCL. When colors are expressed from the luminance compensation layers LCL adjacent to each other, the light-blocking layer BM may prevent or reduce the likelihood of mixture between the colors. The light-blocking layer BM may include at least one of a block pigment, a black dye, or black particles on a base including an organic material. For example, the light-blocking layer BM may include materials such as Cr, CrOx, Cr/CrOx, Cr/CrOx/CrNy, resins (a carbon pigment, an RGB-mixed pigment), graphite, a non-Cr based material, and the like.

Referring to FIG. 17, the light-blocking layer BM may extend along the edge of the first bridge portion 12. In one or more embodiments, a height h of the light-blocking layer BM may be greater than or equal to a height h′ of the luminance compensation layer LCL. According to a manufacturing process, after forming or providing the light-blocking layer BM along the edge of the first bridge portion 12, the luminance compensation layer LCL may be formed in an opening of the light-blocking layer BM.

As the luminance compensation layer LCL that has already developed color is irreversible, a liquid crystal-compensation layer may be further located on the luminance compensation layer LCL. By doing so, when the display device 1 has to implement black color, colored light expressed from the luminance compensation layer LCL may be substantially blocked.

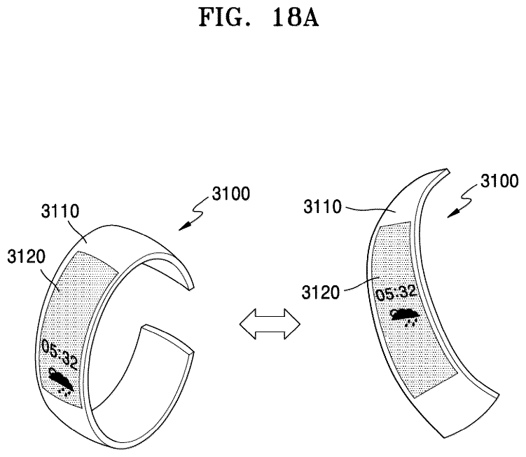

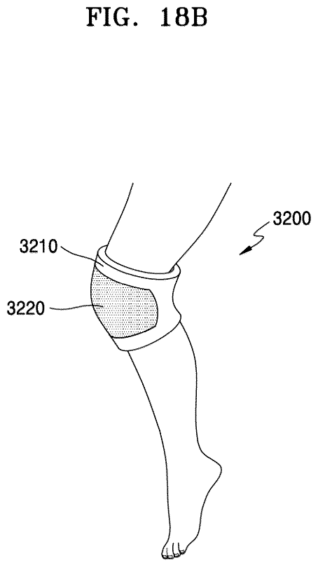

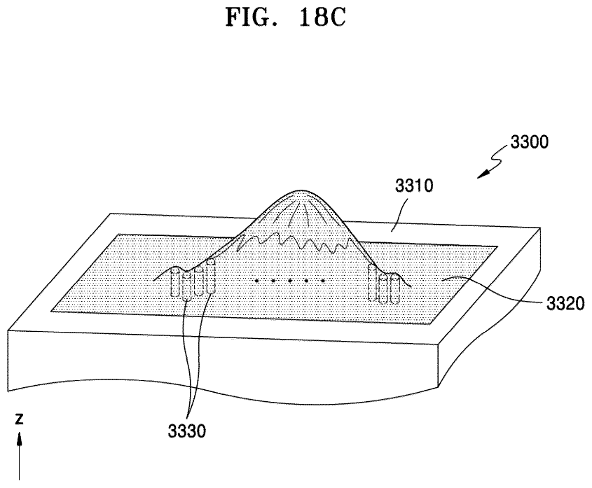

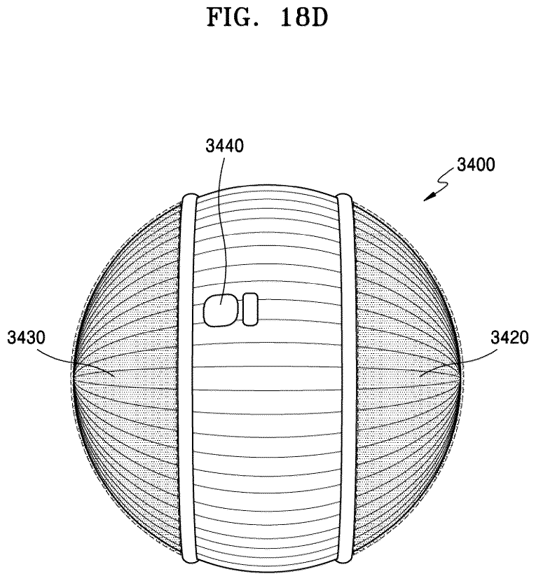

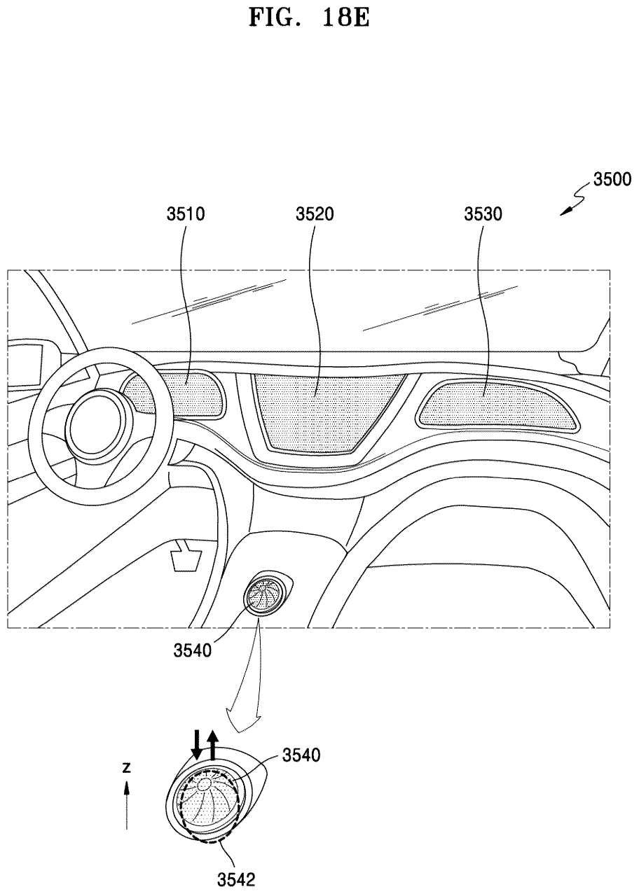

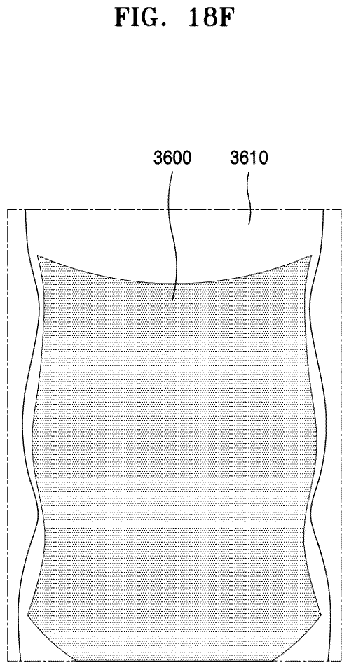

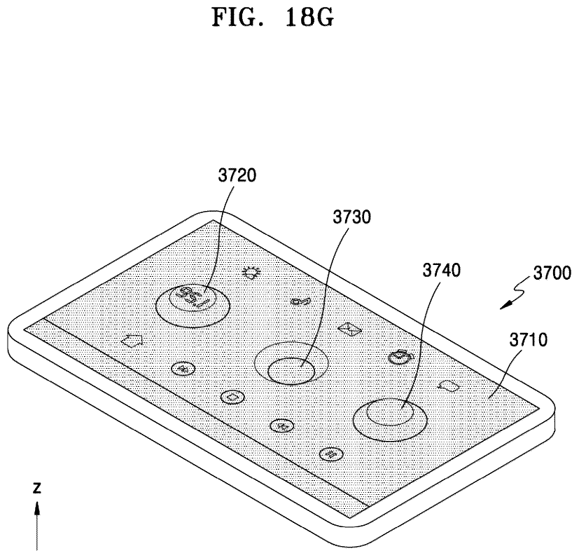

FIGS. 18A to 18G are perspective views schematically illustrating embodiments of an electronic device including a display device according to one or more embodiments of the present disclosure.

Referring to FIG. 18A, the display device according to one or more embodiments may be used to a wearable electronic device 3100 that may be put on a portion of a user's body. The wearable electronic device 3100 may include a body unit 3110 and a display unit 3120 provided in the body unit 3110. The display device according to embodiments may be used as the display unit 3120 of the wearable electronic device 3100. The wearable electronic device 3100 illustrated in FIG. 18A may be transformed. In one or more embodiments, according to choice of the user, the wearable electronic device may be used as a smartwatch or a smartphone.

FIG. 18B illustrates a medical electronic device 3200. In one or more embodiments, the medical electronic device 3200 may include a body unit 3210 and a light-emitting unit 3220. The display device according to embodiments may be used as the light-emitting unit 3220 of the medical electronic device 3200. The light-emitting unit 3220 may be configured to emit in a corresponding wavelength band (e.g., infrared ray, visible ray, and the like) to the body of the user. In one or more embodiments, the body unit 320 may include an elastic fiber material, and may have a structure that may be put on the body of the user.

FIG. 18C illustrates an electronic device 3300 for education. In one or more embodiments, the electronic device 3300 for education may include a display unit 3320 provided in a frame 3310. The display device according to embodiments may be used as the display unit 3320. Images, such as a sea (e.g., a sea having waves), mountains covered with snow, or a volcano with overflowing lava, may be provided through the display unit 3320, and in this case, the display unit 3320 may be stretched in a height direction (e.g., the z direction) by reflecting heights of waves, the mountain, or the volcano. In one or more other embodiments, a portion of the display unit 3320 may have a height sequentially changing in a direction in which the lava flows, thereby three-dimensionally displaying flow of the lava. The electronic device 3300 for education may include a plurality of pins (or a plurality of stroke units) 3330 arranged on a back surface of the display unit 3320 such that the display unit 3320 is stretched in the height direction. As the plurality of pins 3330 move in the third direction (e.g., the z direction or the −z direction), the image expressed in the display unit 3320 may be implemented to have a three-dimensional height. Although the electronic device 3300 for education has been described with reference to FIG. 18C, use of the electronic device is not particularly limited as long as the electronic device provides corresponding image information.

Although an electronic device that may be transformed has been described with reference to the electronic devices illustrated in FIGS. 18A to 18C, the disclosure is not limited thereto. Like in embodiments to be described hereinafter, the display device according to embodiments may be used for an electronic device in which a portion for expressing images (e.g., a screen) is fixed.

FIG. 18D illustrates a robot 3400 as an electronic device according to one or more other embodiments. The robot 3400 may be configured to recognize movements or objects by using a camera unit 3440 and display corresponding images to the user through display units 3420 and 3430. In one or more other embodiments, the display device according to embodiments may extend in various directions as described above, and thus, may be assembled to a body frame having a hemispheric shape. Therefore, the robot 3400 may include the display units 3420 and 3430 having a hemispheric shape.

FIG. 18E illustrates a display device 3500 for vehicle as an electronic device according to one or more other embodiments. The display device 3500 for vehicle may include a cluster 3510, a center information display (CID) 3520, and/or a passenger display. The display device may extend in various directions, and thus, may be used in the cluster 3510, the CID 3520, and/or the passenger display without being constrained to a shape of an inner frame of the vehicle.

Although FIG. 18E illustrates that the cluster 3510, the CID 3520, and/or the passenger display are separated from one another, the disclosure is not limited thereto. In one or more other embodiments, two or more components selected from among the cluster 3510, the CID 3520, and the passenger display may be integrally connected.

In one or more embodiments, the display device 500 for vehicle may include a button 3540 configured to express corresponding images. Referring to an enlarged image illustrated in FIG. 18E, the button 3540 having a hemispheric shape may include an object 3542, which is configured to provide a sense of use of the button 3540 while moving in the z direction or the −z direction, and the display device arranged on the object 3542. In one or more other embodiments, when the object 3542 has a three-dimensionally rounded surface, the display device may also have a three-dimensionally rounded surface.

FIG. 18F illustrates that an electronic device according to one or more embodiments of the present disclosure is an electronic device 3600 for commercial films or exhibitions. In one or more other embodiments, the electronic device 3600 for commercial films or exhibitions may be mounted on a fixed structure 3610, such as a wall or a pillar. When the structure 3610 includes a bump surface, like that illustrated in FIG. 18F, the electronic device 3600 for commercial films or exhibitions may also be arranged along the bump surface of the structure 3610. In one or more other embodiments, the electronic device 3600 for commercial films or exhibitions may be mounted on the structure 3610 by using a thermal contraction film and the like.

FIG. 18G illustrates that an electronic device according to one or more embodiments of the present disclosure includes a controller 3700. The controller 3700 may include an image-type button. For example, the controller 3700 may include a first button area 3720, a second button area 3730, and a third button area 3740, which is obtained as a portion of a display unit 3710 protrudes in the z direction or the −z direction (or is recessed in the z direction). In one or more other embodiments, the first button area 3720 and the third button area 3740 may protrude in the z direction, and the second button area 3730 may protrude in the −z direction (or may be recessed in the z direction).

According to one or more embodiments, there may be provided a display device, in which damage due to stress concentration may be reduced or prevented, or the likelihood substantially reduced, and which may contract in various directions. However, the effect is only an example, and the scope of the disclosure is not limited thereto.

While the disclosure has been described with reference to the embodiments illustrated in the drawings, the descriptions are merely illustrative, and it will be obvious to those skilled in the art that various modifications and other equivalent embodiments may be made based thereon. Therefore, the scope of the disclosure will be determined based on the technical spirit of the following claims and equivalents thereof.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate comprising island portions spaced apart from each other, defining an opening between the island portions, and comprising a bridge portion connecting the island portions;
a light-emitting element above the island portions; and
a luminance compensation layer above the bridge portion, and further comprising a color conversion material configured to change color in response to stress.

2. The display device of claim 1, wherein the color conversion material comprises a material represented by Formula 1 below: 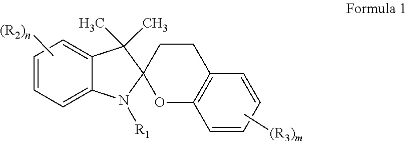
wherein, in Formula 1:
R1 is a substituted or unsubstituted alkyl group having 1 carbon atom to 20 carbon atoms;
R2 and R3 are independently a hydrogen atom, a deuterium atom, a halogen atom, a nitro group, a substituted or unsubstituted oxy group, a substituted or unsubstituted alkyl group having 1 carbon atom to 20 carbon atoms, a substituted or unsubstituted aryl group having 6 ring-forming carbon atoms to 30 ring-forming carbon atoms, or a substituted or unsubstituted heteroaryl group having 2 ring-forming carbon atoms to 30 ring-forming carbon atoms; and
m and n are independently an integer from 0 to 4.

3. The display device of claim 1, wherein a luminance of the luminance compensation layer is configured to increase in response to stress applied to the bridge portion increasing.

4. The display device of claim 1, wherein the luminance compensation layer further comprises a base resin.

5. The display device of claim 1, wherein the luminance compensation layer is spaced apart from the island portions.

6. The display device of claim 1, further comprising at least one groove defined between the island portions and the bridge portion.

7. The display device of claim 6, wherein the luminance compensation layer is separated from the at least one groove.

8. The display device of claim 6, further comprising a protective layer above the island portions to encapsulate the light-emitting element.

9. The display device of claim 8, wherein the protective layer at least partially overlaps the at least one groove, and is spaced apart from the luminance compensation layer.

10. The display device of claim 1, further comprising an insulating layer above the bridge portion, and having a concavo-convex structure,
wherein the luminance compensation layer is directly on the concavo-convex structure of the insulating layer.

11. The display device of claim 1, wherein:
the bridge portion comprises a first bridge portion and a second bridge portion connected to one of the island portions, and extending in different directions, respectively; and
the luminance compensation layer further comprises a first luminance compensation layer above the first bridge portion, and a second luminance compensation layer above the second bridge portion.

12. The display device of claim 11, wherein the first luminance compensation layer is configured to emit light of a first color, and
wherein the second luminance compensation layer is configured to emit light of a second color that is different from the first color.

13. The display device of claim 11, wherein the first luminance compensation layer and the second luminance compensation layer are configured to emit light of a same color.

14. The display device of claim 1, wherein the luminance compensation layer comprises sub-luminance compensation layers spaced apart from each other, and
wherein the sub-luminance compensation layers comprise a first sub-luminance compensation layer and a second sub-luminance compensation layer adjacent to each other, and configured to emit light of different respective colors.

15. The display device of claim 1, wherein the bridge portion has a first width, and
wherein the luminance compensation layer has a second width that is substantially equal to the first width.

16. The display device of claim 1, wherein the bridge portion has a first width, and
wherein the luminance compensation layer has a second width that is less than the first width.

17. The display device of claim 16, wherein the luminance compensation layer is at an edge area of the bridge portion adjacent the island portions.

18. The display device of claim 1, further comprising a light-blocking layer around the luminance compensation layer in plan view.

19. An electronic device comprising a display device comprising:
a substrate comprising island portions spaced apart from each other, defining an opening between the island portions, and further comprising a bridge portion connecting the island portions;
a light-emitting element above the island portions; and
a luminance compensation layer above the bridge portion, and comprising a color conversion material configured to change color in response to stress.

20. The electronic device of claim 19, further comprising a wearable device, a medical device, a device for education, a robot, a device for a vehicle, a device for commercial films or exhibitions, or a controller.
